(19) United States
(12) Patent Application Publication
(10) Pub. No.: US 2025/0096149 A1
(43) Pub. Date: Mar. 20, 2025

(54) SEMICONDUCTOR DEVICE WITH A SILICON CARBIDE PORTION AND A GLASS STRUCTURE AND METHOD OF MANUFACTURING

(71) Applicant: Infineon Technologies AG, Neubiberg (DE)

(72) Inventors: Rudolf Elpelt, Erlangen (DE); Francisco Javier Santos Rodriguez, St.Jakob im Rosental (AT); Bernd Zippelius, Erlangen (DE); Antonio Vellei, Villach (AT); Alexander Breymesser, Villach (AT)

(21) Appl. No.: 18/885,846

(22) Filed: Sep. 16, 2024

(30) Foreign Application Priority Data
Sep. 20, 2023 (DE) 102023125529.0

(51) Int. Cl. H01L 23/544; H01L 21/04; H01L 23/31; H01L 29/06; H01L 29/16; H01L 29/66; H01L 29/78; H01L 29/872

(52) U.S. Cl. CPC H01L 23/544; H01L 21/045; H01L 23/3171; H10D 8/051; H10D 8/605; H10D 12/031; H10D 30/668; H10D 62/107; H10D 62/8325; H01L 2223/5446

(57) ABSTRACT

A semiconductor device includes a single-crystalline silicon carbide portion with a first surface, an opposite second surface, and a third surface extending from the first surface in a direction of the second surface. Along the third surface, hydrogen atoms and/or atoms of one or more nonmetal elements other than silicon and having an atomic number greater than six saturate dangling bonds of the silicon carbide portion and/or a passivating coating is in direct contact with the third surface. The semiconductor device further includes a glass structure and an interface layer structure between the third surface and the glass structure.

### TECHNICAL FIELD

The present disclosure relates to a semiconductor device with a silicon carbide portion and a glass structure. More particularly, the present disclosure relates to a high voltage semiconductor device having an edge termination structure with a glass structure for high blocking voltage capability.

### BACKGROUND

In a vertical power semiconductor device, a load current flows in a vertical direction between a front side and a rear side of a semiconductor die in a conducting mode. In a blocking mode, the vertical power semiconductor device withstands a large terminal voltage. For example, a power semiconductor diode is forward biased in conducting mode and reverse biased in blocking mode, and a power semiconductor switch in conducting mode when switched on and in blocking mode when switched off. The maximum terminal voltage the power semiconductor device can withstand is the blocking voltage. The blocking voltage depends on material properties and the design of the power semiconductor device. Since a lateral surface of a semiconductor die is comparatively rough with low crystal quality, a rear side potential is typically brought to the front side along the edge of the semiconductor die to keep the lateral surface of the semiconductor die free from electric fields, and a lateral field termination structure in a termination region shapes the electric field to avoid field crowding and ensure a high blocking voltage.

There is an ongoing need for area-efficient power semiconductor devices with high blocking voltage capability.

### SUMMARY

Instead of providing an area-consuming lateral field termination structure, the embodiments of the present disclosure use a vertical field termination structure.

A semiconductor device in accordance with the pertinent disclosure includes a single-crystalline silicon carbide portion that includes a first surface, an opposite second surface and a third surface extending from the first surface in direction of the second surface. Along the third surface, hydrogen atoms and/or atoms of one or more nonmetal elements other than silicon and having an atomic number greater than six saturate dangling bonds of the silicon carbide portion and/or a passivating coating is in direct contact with the third surface. The semiconductor device further includes a glass structure and an interface layer structure between the third surface and the glass structure.

The combination of the glass structure with the passivated and/or saturated dangling bonds along the third surface voltage facilitate a more vertical field termination with a blocking capability adjusted to the blocking capability in a central device region of the semiconductor device. The vertical field termination structure can be designed to occupy less horizontal chip area than a comparable conventional lateral field termination, saving material costs.

The present disclosure is further related to a method of manufacturing a semiconductor device, wherein the method includes: forming a separation trench in a main surface of a single-crystalline silicon carbide layer, wherein the separation trench surrounds a die portion of the silicon carbide layer; treating at least a first sidewall of the separation trench of the silicon carbide layer in a conditioning process, wherein dangling bonds of the silicon carbide layer are passivated; forming an interface layer on the first sidewall of the separation trench; forming a glass fill structure in the separation trench; and separating the silicon carbide layer along a vertical separation line parallel to the separation trench.

Those skilled in the art will recognize additional features and advantages by reading the following detailed description and viewing the accompanying drawings.

### BRIEF DESCRIPTION OF THE DRAWINGS

The accompanying drawings are provided for further understanding of the embodiments and form an integral part of this description. The drawings illustrate embodiments of a semiconductor device and a method of manufacturing and, together with the description, explain the principles underlying the embodiments. Further embodiments are described in the following detailed description and in the claims. Features of the various embodiments may be combined with each other.

FIG. 1A is a schematic vertical cross-sectional view of a portion of a semiconductor device having a field termination structure based on passivated dangling bonds along a third surface at the chip edge, a glass structure, and an interface layer structure between the third surface and the glass structure according to an embodiment.

FIG. 1B is a schematic vertical cross-sectional view of a portion of a semiconductor device having a field termination structure based on saturated dangling bonds along a third surface at the chip edge, a glass structure, and an interface layer structure between the third surface and the glass structure according to an embodiment.

FIG. 2A is a schematic vertical cross-sectional view of a portion of a semiconductor device having a field termination structure based on passivated dangling bonds along a third surface in a termination trench, a glass structure in the termination trench, and an interface layer structure between the third surface and the glass structure according to an embodiment.

FIG. 2B is a schematic vertical cross-sectional view of a portion of a semiconductor device having a field termination structure based on saturated dangling bonds along a third surface in a termination trench, a glass structure in the termination trench, and an interface layer structure between the glass structure and the third surface according to an embodiment.

FIG. 3A to FIG. 3D are schematic vertical cross-sectional views of portions of semiconductor devices with edge structures according to further embodiments.

FIG. 4 to FIG. 6 are schematic vertical cross-sectional views of portions of semiconductor devices according to embodiments with edge structures including an interface layer structure ending at a first metal structure.

FIG. 7 to FIG. 9 are schematic vertical cross-sectional views of portions of semiconductor devices according to embodiments with edge structures including an interface layer structure with a vertical extent smaller than a vertical extent of a first metal structure at the front side.

FIG. 10 to FIG. 12 are schematic vertical cross-sectional views of portions of semiconductor devices according to embodiments with edge structures including an interface layer structure partially covering a first metal structure at the front side.

FIG. 13 to FIG. 14 are schematic vertical cross-sectional views of portions of semiconductor devices according to embodiments with edge structures including an interface layer structure partially covered by a first metal structure at the front side.

FIG. 15 is a schematic vertical cross-sectional view of a portion of a semiconductor device according to an embodiment with a body/anode region laterally separated from an edge structure.

FIG. 16 to FIG. 17 are schematic vertical cross-sectional views of portions of semiconductor devices according to embodiments with field relaxing structures between the body/anode regions and the edge structure.

FIG. 18 is a schematic vertical cross-sectional view of a portion of a semiconductor device according to an embodiment with a surface layer between the first surface and a field relaxing structure.

FIG. 19 to FIG. 20 are schematic vertical cross-sectional views of portions of semiconductor devices according to embodiments with field relaxing structures including weakly doped supplementary structures.

FIG. 21A to FIG. 21E are schematic vertical cross-sectional views of a portion of a silicon carbide layer for illustrating a method of manufacturing a semiconductor device with an edge structure for vertical field termination according to an embodiment that includes dicing along separation lines in separation trenches.

FIG. 22 is a schematic vertical cross-sectional view of a portion of a silicon carbide layer for illustrating a method of manufacturing a semiconductor device with an edge structure for vertical field termination according to an embodiment that includes dicing along separation lines between separation trenches.

FIG. 23 is a schematic plan view of a portion of a silicon carbide layer for illustrating a method of manufacturing a semiconductor device with an edge structure for vertical field termination according to an embodiment that includes dicing along separation lines in separation trenches.

FIG. 24 is a schematic plan view of a portion of a silicon carbide layer for illustrating a method of manufacturing a semiconductor device with an edge structure for vertical field termination according to an embodiment that includes dicing along separation lines between separation trenches.

FIG. 25A to FIG. 25F are schematic vertical cross-sectional views of a portion of a silicon carbide layer for illustrating a method of manufacturing a semiconductor device according to an embodiment that includes forming separation trenches after forming gate electrode structures and a first metal structure at a front side.

FIG. 26A to FIG. 26F are schematic vertical cross-sectional views of a portion of a silicon carbide layer for illustrating a method of manufacturing a semiconductor device according to an embodiment that includes forming separation trenches after forming gate electrode structures and before forming a first metal structure at a front side.

FIG. 27A to FIG. 27C are schematic vertical cross-sectional views of a portion of a silicon carbide layer for illustrating a method of manufacturing a semiconductor device according to an embodiment that includes forming a first metal structure covering a portion of the edge structure at a front side.

FIG. 28A to FIG. 28C are schematic vertical cross-sectional views of a portion of a silicon carbide layer for illustrating a method of manufacturing a semiconductor device according to an embodiment that includes forming an edge structure extending through the silicon carbide layer.

FIG. 29A to FIG. 29C are schematic vertical cross-sectional views of a portion of a silicon carbide layer for illustrating a method of manufacturing a semiconductor device according to an embodiment that includes forming separation trenches before forming gate electrode structures in gate trenches.

### DETAILED DESCRIPTION

In the following detailed description, reference is made to the accompanying drawings which form a part of this document and in which certain embodiments of a semiconductor device and a method of manufacturing are shown as illustrations. Structural or logical changes may be made to the illustrated embodiments without departing from the scope of the present disclosure. For example, features shown or described for one embodiment may be used on or in conjunction with other embodiments, resulting in another embodiment. The present disclosure is intended to include such modifications and variations. The embodiments are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “comprising” and the like are open-ended, and the terms indicate the presence of certain structures, elements or features but do not preclude the presence of additional elements or features. The articles “a”, “an” and “the” include both the plural and singular, unless the context clearly indicates otherwise.

The expression “and/or” should be interpreted to cover all possible conjunctive and disjunctive combinations, unless expressly noted otherwise. For example, the expression “A and/or B” should be interpreted to mean A but not B, B but not A, or both A and B. The expression “at least one of” should be interpreted in the same manner as “and/or”, unless expressly noted otherwise. For example, the expression “at least one of A and B” should be interpreted to mean A but not B, B but not A, or both A and B.

The term “power semiconductor device” refers to semiconductor devices with a voltage blocking capability of at least 30 V, for example 48 V, 100 V, 600 V, 1.6 kV, 3.3 kV or more and with a nominal on-state current or forward current of at least 200 mA, for example 1 A, 10 A or more.

MOSFETS (metal oxide semiconductor field effect transistor) are voltage-controlled devices and include all types of IGFETs (insulated gate field effect transistors) with gate electrodes based on doped semiconductor material and/or metal and with gate dielectrics made of oxide and/or dielectric materials other than oxides.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

Ranges given for physical dimensions include the boundary values. For example, a range for a parameter y from a to b reads as a ≤y≤b. The same holds for ranges with one boundary value like “at most” and “at least”.

The term “on” is not to be construed as meaning only “directly on”. Rather, if one element is positioned “on” another element (e. g., a layer is “on” another layer or “on” a substrate), a further component (e.g., a further layer) may be positioned between the two elements (e.g., a further layer may be positioned between a layer and a substrate if the layer is “on” said substrate).

Two adjoining doping regions in a semiconductor layer may form a semiconductor junction. Two adjoining doping regions of the conductivity type and with different dopant concentrations form a unipolar junction, e.g., an n/n+ or p/p+ junction along a boundary surface between the two doping regions. At the unipolar junction a dopant concentration profile orthogonal to the unipolar junction may show a step or a turning point, at which the dopant concentration profile changes from being concave to convex, or vice versa. Two adjoining doping regions of complementary conductivity form a pn junction.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

The present disclosure is related to a semiconductor device that may include a single-crystalline silicon carbide portion with a first surface, an opposite second surface and a third surface extending from the first surface in direction of the second surface.

The first and second surfaces may be parallel or at least approximately parallel to each other, wherein planes coplanar with the first and second surfaces may intersect each other at an angle of no more than 4 degrees. The first surface may be planar or ribbed and trenches may extend from the first surface into the silicon carbide portion. The plane of the first surface defines horizontal (lateral) directions. A surface normal to the first surface defines a vertical direction orthogonal to the horizontal directions.

The third surface may be inclined with respect to the first plane by an angle in a range from 70 degrees to 110 degrees, for example in a range from 80 degrees to 100 degrees. The third surface may connect the first surface and the second surface. Alternatively, the third surface ends at a distance to the second surface.

Along the third surface, hydrogen atoms and/or atoms of one or more nonmetal elements other than silicon and having an atomic number greater than six saturate dangling bonds of the silicon carbide portion and/or a passivating coating is in direct contact with the third surface.

The dangling bonds along the third surface may include silicon face dangling bonds and carbon face dangling bonds. Auxiliary atoms of one or more nonmetal elements other than silicon and carbon may saturate the dangling bonds to a large extent. The nonmetal elements may include at least one of: nitrogen, oxygen, phosphorus, sulfur, selenium, the halogens (group 17 elements), or the noble gases (group 18 elements). Metal atoms may be absent or almost completely absent along the third surface. Presence of the auxiliary atoms and absence of metal atoms can be detected by auger electron spectroscopy (AES), by way of example. For example, along the third surface, a density of metal atoms may be at most 10%, e.g., at most 1% or most 0.1% of a density of nonmetal atoms other than carbon and silicon.

The passivating coating may be a layer or layer stack of uniform thickness that may be formed by at least one, two, ten or ten dense continuous atomic layers. The passivating coating may passivate the dangling bonds and/or metal atoms such that no voltage breakdown forms along the third surface when a blocking voltage less than a nominal maximum blocking voltage is applied between the front side and the rear side of the semiconductor device.

In both alternatives, the dangling bonds and/or metal atoms are rendered ineffective at least to a large extent. For example, the density of interface states (Dit) along the third surface is at most 5E12 1/cm²eV, at most 2E12 1/cm²eV or at most 1E12 1/cm²eV.

The semiconductor device may further include a glass structure and an interface layer structure between the third surface and the glass structure.

The glass structure may provide sufficient dielectric strength to avoid a voltage breakdown between the front side and the rear side along a path outside the silicon carbide portion parallel to the third surface. The interface layer structure allows to decouple the processing of the glass structure from the passivation/saturation of the dangling bonds and/or may improve adhesion between the glass structure and the silicon carbide portion. The interface layer structure may provide sufficient dielectric strength to avoid a voltage breakdown between the front side and the rear side through the interface layer structure.

The interface layer structure, the glass structure and, if applicable, the passivating coating may form an edge structure that provides an area-efficient field termination structure blocking an electrical field between first conductive structures at the frontside of the silicon carbide portion and second conductive structures at the rear side of the silicon carbide structure. In a blocking mode of the semiconductor device, the rear side potential can be confined to the rear side of the silicon carbide portion. The blocking mode may be the reverse-biased mode of a power semiconductor diode or the off-state of a power semiconductor switch. The edge structure can be combined with a lateral termination structure with reduced width. Alternatively, the lateral termination structure can be completely omitted.

According to an embodiment, the atoms of the one or more nonmetal element may include at least one of nitrogen atoms, oxygen atoms, and phosphorus atoms.

Nitrogen, oxygen and phosphorus atoms can be applied by proved and tested processes using well-established techniques.

According to an embodiment, the passivating coating may include a layer structure that includes at least one of: an oxide layer, a nitride layer, an oxynitride layer or a carbon-containing layer.

The oxide layer may be an oxide-based layer, e.g. a silicon oxide layer (SiₓO_{y}, e.g. SiO₂) or a silicon carbon oxide layer (SiₓC_{y}O_{z}). The nitride layer may be a nitride-based layer, e.g. a silicon nitride layer (SiₓN_{y}, e.g. Si₃N₄) or a silicon carbon nitride layer (SiₓC_{y}N_{z}). The oxynitride layer may be a silicon oxynitride layer (SiₓO_{y}N_{z}) or a silicon carbon oxynitride layer (SiCₓO_{y}N_{z}).

For example, the passivating coating may be or may include an oxygen-containing layer formed by an O₂ flash, a silicon oxide layer formed by atomic layer deposition (ALD), or an annealed silicon oxide layer obtained in a deposition process using tetraethyl orthosilane (TEOS) as precursor. For example, the passivating coating is a layer stack that includes one or more deposited silicon dioxide layers containing SiO₂ and one or more deposited silicon nitride layers containing Si₃N₄.

According to an embodiment, the third surface may include an inner sidewall of a trench structure laterally surrounding a center portion of the silicon carbide portion.

The trench structure may laterally separate the center portion from a peripheral portion between the trench structure and a lateral surface of the silicon carbide portion, wherein the lateral surface extends from the edge of the first surface to the edge of the second surface.

The trench structure may have a uniform vertical extent (“depth”), a uniform lateral width, and/or a uniform lateral distance to the lateral edge of the silicon carbide portion. The trench structure may form a continuous frame around the center portion. The frame may be rectangular with four orthogonal, straight sections. It may be possible that the frame has rounded or flattened/snipped corners between the straight sections.

The atoms s of hydrogen and/or one or more nonmetal elements other than silicon and having an atomic number greater than six saturate dangling bonds of the silicon carbide portion along the inner sidewall of the trench structure oriented to the center portion. In addition, the atoms of hydrogen and/or one or more nonmetal elements other than silicon and having an atomic number greater than six may saturate dangling bonds of the silicon carbide portion along an outer sidewall of the trench structure oriented to the peripheral portion and/or along a bottom of the trench structure oriented to the second surface and connecting the inner sidewall and the outer sidewall. The interface layer structure may cover the inner sidewall, the outer sidewall, and the bottom with uniform thickness. The glass structure fills the space between the various sections of the interface layer structure.

Alternatively or in addition, a passivating coating may be in direct contact with the complete inner sidewall of the trench structure oriented to the center portion. In addition, the passivating coating may be in direct contact with the outer sidewall of the trench structure and/or with the bottom of the trench structure. The interface layer structure may cover all sections of the passivating coating with uniform thickness. The glass structure fills the space between the various sections of the interface layer structure.

According to another embodiment, the third surface may form at least a portion of a lateral surface connecting an edge of the first surface and an edge of the second surface.

The lateral surface may include the third surface extending from the first surface toward the second surface, a fourth surface extending from the second surface toward the first surface, and a fifth surface connecting the edges of the third and fourth surfaces remote from the first and second surfaces. The third, fourth and fifth surface in combination may form a step-like surface. The fourth surface may extend in the vertical direction and/or parallel to the third surface. The third surface may be vertically oriented or inclined to the vertical direction by no more than 20 degrees. The fifth surface may extend horizontally or be inclined no more than 20 degrees from the horizontal direction. Alternatively, the lateral surface may include more than one step extending outwardly from the silicon carbide portion at a distance to the first surface and at a distance to the second surface.

According to an embodiment, the third surface connects the edge of the first surface and the edge of the second surface.

The third surface forms the lateral surface connecting the edge of the first surface and the edge of the second surface. The third surface may be straight and extend vertically from the edge of the first surface to the edge of the second surface.

Auxiliary atoms of hydrogen and/or one or more nonmetal elements other than silicon and having an atomic number greater than six saturate dangling bonds of the silicon carbide portion along the third surface, that is, along the complete lateral surface. The interface layer structure may be in direct contact with the third surface.

Alternatively or in addition, a passivating coating is formed in direct contact with the third surface, that is, along the complete lateral surface. The interface layer structure covers the passivating coating with uniform thickness.

According to an embodiment, the silicon carbide portion may include a heavily doped base portion of a first conductivity type and a less heavily doped main layer of the first conductivity type between the first surface and the base portion, and wherein the third surface laterally exposes the main layer and the base portion.

The main layer and the base portion may form a unipolar junction, wherein an interface between the main layer and the base portion is at least approximately horizontal. Further horizontal layers or horizontally layered structures may be formed between the first surface and the main layer, between the main layer and the base portion and/or between the base portion and the second surface. The third surface may expose the complete lateral surface of the main layer and may expose a portion of the lateral surface of the base portion or the complete lateral surface of the base portion.

According to an embodiment, the interface layer structure may include a surface portion on the first surface.

The interface layer structure may include the surface portion in addition to a trench portion formed at the third surface. The trench portion and the surface portion may be connected to each other to form a continuous one-part structure. The trench portion and the surface portion may be layered portions of the same layer thickness. The surface portion may cover an edge region of the first surface directly along an edge or transition between the first surface and the third surface.

According to an embodiment, the glass structure may include a horizontal part formed on the interface layer structure.

The glass structure may include the horizontal part in addition to a trench part formed in the volume between the interface layer structure and the lateral surface of the semiconductor device. A first portion of the horizontal part may be formed directly on the surface portion of the interface layer structure and a second portion of the horizontal part is formed directly on the trench part of the glass structure. The horizontal part and the trench part may be connected to each other and form a continuous, one-part structure with an L-shaped or T-shaped vertical cross-section. The horizontal part covers at least a section of the surface portion of the interface layer structure directly adjacent to the trench part.

According to an embodiment, a first metal structure may be in direct contact with the first surface of the silicon carbide portion and the interface layer structure.

The first metal structure may be formed on a front side of the silicon carbide portion. The first metal structure and doped regions in the silicon carbide portion may form an electric contact, wherein the electric contact may be a low-resistive ohmic contact or a Schottky contact. For example, the first metal structure includes a contact layer and a principal layer. The contact layer may contain metal atoms forming a stable, high-conductive phase with silicon and carbon and/or silicon carbide. Alternatively, the contact layer is based on a material forming a Schottky contact with a suitable doped region in the silicon carbide portion. The principal layer may contain aluminum and/or copper. The first metal structure and the interface layer structure form an interface tilted to the first surface.

According to an embodiment, a first vertical extent v1 of the surface portion of the interface layer structure may be at least 80% and at most 120% of a second vertical extent v2 of the first metal structure. For example, the first vertical extent v1 and the second vertical extent v2 can be equal.

The first vertical extent v1 and the second vertical extent v2 may have the same target values and a difference between the first vertical extent v1 and the second vertical extent v2 may be process-related.

According to another embodiment, a first vertical extent v1 of the surface portion of the interface layer structure may be less than 80% of a second vertical extent v2 of the first metal structure.

For example, the first vertical extent v1 of the surface portion of the interface layer structure is at most 60% or 50% of the second vertical extent v2 of the first metal structure.

According to an embodiment, a total thickness v3 of the interface layer structure and the horizontal part of the glass structure and the second vertical extent v2 of the first metal structure may be equal.

The total thickness v3 of the interface layer structure and the horizontal part of the glass structure and the second vertical extent v2 of the first metal structure may have the same target values and a difference between the total thickness v3 and the second vertical extent v2 may be process-related.

Top surfaces of the glass structure and the first metal structure averted from the silicon carbide portion may be essentially in the same plane. The glass structure and the first metal structure form an interface tilted to the first surface.

According to an embodiment, the first metal structure and the horizontal part of the glass structure may be laterally separated.

An auxiliary gap exposing a top surface of the interface layer structure may laterally separate the glass structure and the first metal structure.

According to an embodiment, in a lateral direction the surface portion of the interface layer structure may end at the first metal structure and the first metal structure may end at the surface portion of the interface layer structure.

The first metal structure and the surface portion of the interface layer structure may form an interface with a single surface tilted to the first surface.

According to another embodiment, the surface portion of the interface layer structure and the first metal structure may overlap in the vertical direction.

For example, the surface portion of the interface layer structure may cover a portion of the first metal structure. The surface portion of the interface layer structure laterally overlaps the first metal structure, wherein the surface portion includes a step and covers a lateral surface of the first metal structure oriented to the interface layer structure and a peripheral portion of the first metal structure directly along the lateral surface of the first metal structure.

According to another example, the first metal structure may cover a portion of the surface portion of the interface layer structure. The first metal structure laterally overlaps the surface portion of the interface layer structure, wherein the first metal structure includes a step and covers a lateral surface of the surface portion oriented to the first metal structure and a peripheral portion of the surface portion directly along the lateral surface of the surface portion.

According to an embodiment, the semiconductor device may further include a body/anode region of a second conductivity type complementary to the first conductivity type, wherein the body/anode region is formed between the main layer and the first surface.

The body/anode region may be in direct contact with the edge structure or may be separated from the edge structure. For example, a separation region of the first conductivity type may extend from the first surface to the main layer along the edge structure.

The body/anode region may form or include the anode region of a vertical power semiconductor diode with a forward current flowing along the vertical direction. Alternatively, the body/anode region may include the body regions of transistor cells of a vertical power semiconductor transistor with a drain current flowing along the vertical direction.

According to an embodiment, the body/anode region may be formed at a distance to the interface layer structure and the passivating coating.

For example, the body/anode region is formed at a lateral distance to an edge structure that includes the interlayer structure and the glass structure or the interlayer structure, the glass structure and the passivating coating.

According to an embodiment, the semiconductor device may further include a field relaxing structure of the second conductivity type, wherein the field relaxing structure laterally surrounds the body/anode region, and wherein a net doping of the field relaxing structure is lower than a net doping in the body/anode region.

In the vertical direction, the field relaxing structure may be formed between the less heavily doped main layer and the first surface. In the lateral direction, the field relaxing structure may be formed between the body/anode region and the edge structure.

According to an embodiment, the field relaxing structure may be in direct contact with the interface layer structure or the passivating coating.

According to another embodiment, the field relaxing structure is formed at a distance to the interface layer structure and the passivating coating.

The field relaxing structure may be separated from the edge structure. For example, a separation region of the first conductivity type may extend from the first surface to the main layer along the edge structure.

According to an embodiment, the field relaxing structure may include one single field relaxing ring. The field relaxing ring may be laterally separated from the body/anode region.

According to another embodiment, the field relaxing structure may include a plurality of laterally separated field relaxing rings.

Separation regions of the first conductivity type may extend from the direction of the first surface to the main layer between neighboring field relaxing rings and between an innermost field relaxing ring and the body/anode region.

According to an embodiment, the semiconductor device may further include a surface layer of the first conductivity type between the first surface and the field relaxing structure.

According to an embodiment, the field relaxing structure may include a supplementary structure, wherein the supplementary structure is in direct contact with the field relaxing rings and has a lower net doping than the field relaxing rings. The supplementary structure has the second conductivity type.

The supplementary structure is formed between the first surface and the main layer, or between the surface layer and the main layer. The supplementary structure may form a connection layer extending parallel to the first surface. The field relaxing rings may extend into and overlap with the connection layer.

According to an embodiment, the supplementary structure may include a plurality of supplementary rings, each supplementary ring formed between neighboring field relaxing rings or between an innermost field relaxing ring and the body/anode region. The supplementary rings have the second conductivity type.

The present disclosure is further related to a method of manufacturing a semiconductor device, wherein the method may include: forming a separation trench in a main surface of a single-crystalline silicon carbide layer, wherein the separation trench surrounds a die portion of the silicon carbide layer; treating a first sidewall of the separation trench of the silicon carbide layer in a conditioning process, wherein dangling bonds of the silicon carbide layer are passivated; forming an interface layer on the first sidewall of the separation trench; forming a glass fill structure in the separation trench; and separating the silicon carbide layer along a vertical separation line parallel to the separation trench.

The conditioning process may include terminating the dangling bonds or passivating the dangling bonds in another way, e.g., by means of a suitable, dense passivating coating. The dangling bonds are rendered ineffective at least to a large extent. In addition, metal atoms may be removed or rendered inactive to a high degree. After the conditioning process, the density of interface states (Dit) along the third surface is at most 5E12 1/cm²eV, at most 2E12 1/cm²eV or at most 1E12 1/cm²eV.

The conditioning process may be effective exclusively for the first sidewall of the separation trench, or for any combination of the first sidewall with the second sidewall, the bottom of the separation trench, one or more sections of the main surface, and inner surfaces of gate trenches.

The interface layer may be formed exclusively on the first sidewall of the separation trench, or on any combination of the first sidewall with the second sidewall, the bottom of the separation trench, and one or more sections of the main surface.

According to an embodiment, the vertical separation line may run through and along the separation trench.

According to an embodiment, treating the first sidewall may include a plasma-based flash passivation.

The plasma-based flash passivation may include striking a gas such as oxygen gas (O₂), nitrogen gas (N₂), or sulfur dioxide gas (SO₂) to form a plasma of dissociated radicals to react with the exposed surface of the silicon carbide layer. A passivating layer of material (e.g., oxide or nitride) may be formed on the surface. Metal atoms may be removed or rendered inactive.

In some implementations, the gas is exposed to RF power delivery in a relatively short amount of time, such as between about 0.5 seconds and about 5 seconds, to form the plasma for plasma-based flash passivation. The dissociated radicals react with atoms along the exposed surface of the silicon carbide layer. The dissociated radicals may remove impurity atoms, e.g. metal atoms, trapped along the exposed surface of the silicon carbide layer and/or oxidize silicon or carbon. For example, the dissociated radicals may form a thin and dense silicon oxide layer or a dense layer containing stoichiometric or non-stoichiometric silicon dioxide SiO₂ and/or stoichiometric or non-stoichiometric silicon carbon oxide SiOC.

According to an embodiment, treating the first sidewall may include depositing a passivation coating using a precursor material containing silicon as a main component.

The precursor material may be a silane, for example monosilane SiH₄ or TEOS. Forming the passivation coating may include depositing a conformal atomic layer with at least one, two, five or ten single atomic layers, using an oxygen containing precursor and a silicon containing precursor, or a precursor containing oxygen and silicon. Alternatively, the passivation coating may be formed by chemical vapor deposition (CVD) using TEOS as precursor material.

According to an embodiment, forming the glass fill structure may include pressing a glass material into the separation trench.

For example, forming the glass fill structure may include a glass embossing process.

According to an embodiment, the method may further include forming a contact layer in a contact section of the main surface, wherein the contact layer and the silicon carbide layer form an ohmic contact (e.g. a low-resistive ohmic contact) and/or a Schottky contact, and forming a principal layer on the contact layer, wherein the principal layer comprises at least one of aluminum (Al) and copper (Cu).

According to an embodiment, the separation trench may be formed after forming the principal layer.

According to an embodiment, the separation trench may be formed after forming the contact layer and the principal layer may be formed after forming the glass fill structure.

According to an embodiment, a section of the principal layer may be formed on a section of the glass fill structure.

According to an embodiment, the method may further include thinning, before separating, the silicon carbide layer from a side opposite to the main surface, wherein the glass fill structure (e.g. a bottom of the glass fill structure) is exposed after the thinning.

According to an embodiment, the method may further include forming gate electrode structures in the silicon carbide layer, wherein forming the gate electrode structures includes forming gate trenches extending from the main surface into the silicon carbide layer and forming gate electrodes in the gate trenches, and wherein the separation trench is formed before forming the gate electrodes.

According to an embodiment, the method may further include filling the separation trench with an auxiliary material before forming the gate electrodes, and removing the auxiliary material after forming the contact layer.

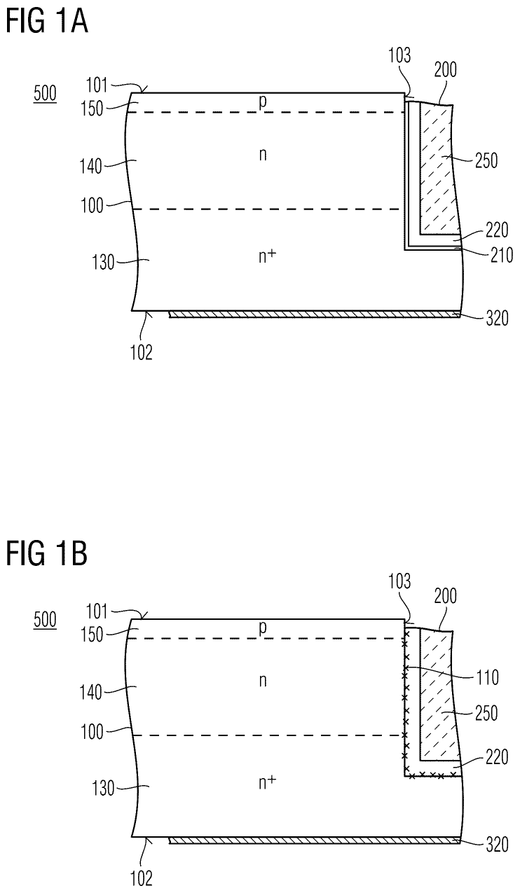

FIG. 1A and FIG. 1B show a semiconductor device 500 with a single-crystalline silicon carbide portion 100. The silicon carbide portion 100 has a first surface 101 and an opposite second surface 102. A third surface 103 extends from the first surface 101 in direction of the second surface 102 without reaching the second surface 102.

The first surface 101 is located at a frontside of the silicon carbide portion 100. The first surface 101 may be planar or may include first coplanar surface sections between trenches extending from a first plane defined by the first coplanar surface sections of the first surface 101 into the silicon carbide portion 100. The second surface 102 is located at an opposite rear side of the silicon carbide portion 100 and may be planar or may include second coplanar surface sections separated by trenches extending from a second plane defined by the second coplanar surface sections into the silicon carbide portion 100. The first plane and the second plane may be tilted to each other by at most 4 degrees. In the illustrated embodiment, the first surface 101 and the second surface 102 are parallel to each other.

The first surface 101 has a lateral extent in two orthogonal horizontal directions defined by an x axis and a y axis. A surface normal to the first surface 101 defines a vertical direction along a z axis.

The third surface 103 is inclined with respect to the first plane by an angle in a range from 70 degrees to 110 degrees. The third surface 103 ends at a distance to the second surface 102. The third surface 103 may be part of a sidewall of a trench extending from the first surface 101 into the silicon carbide portion 100 or may be part of a lateral surface of the silicon carbide portion 100, wherein the lateral surface connects an edge of the first surface 101 with an edge of the second surface 102.

The silicon carbide portion 100 includes a heavily doped base portion 130 of a first conductivity type and a less heavily doped main layer 140 of the first conductivity type between the first surface 101 and the base portion 130. A body/anode region 150 of a second conductivity type complementary to the first conductivity type is formed between the main layer 140 and the first surface 101.

In the illustrated embodiments, the first conductivity type is n type and the second conductivity type is p type. According to other embodiments, the first conductivity type is p type and the second conductivity type is n type.

The body/anode region 150 may form the anode region of a vertical power semiconductor diode with a forward current flow along the vertical direction. Alternatively, the body/anode region 150 may include the body regions of transistor cells of a vertical power semiconductor transistor with a load current flow along the vertical direction.

The third surface 103 forms the sidewall of an indentation or a trench that extend from the first surface 101 into the base portion 130. The indentation or the trench laterally exposes the body/anode region 150, the main layer 140, and an upper section of the base portion 150. The body/anode region 150, the main layer 140 and the base portion 150 are in direct contact with an edge structure 200.

A first metal structure formed on the first surface 101 may be in direct contact with the body/anode region 150. A second metal structure 320 directly formed on the second surface 102 is in direct contact with the base portion 130.

In FIG. 1A the edge structure 200 includes a passivating coating 210 that is in direct contact with the third surface 103. The passivating coating 210 is a dense layer of uniform thickness formed and may be formed by a small number of continuous atomic layers.

The passivating coating renders inactive dangling bonds of the silicon carbide and/or metal atoms along the third surface 103 at least to a large extent. For example, a density of interface states (Dit) along the third surface 103 is at most 5E12 1/cm²eV, at most 2E12 1/cm²eV or at most 1E12 1/cm²eV.

In FIG. 1B auxiliary atoms 110 saturate (terminate) dangling bonds of the silicon carbide portion 100. The auxiliary atoms 110 include hydrogen atoms and/or atoms of one or more nonmetal elements other than silicon and having an atomic number greater than six. The dangling bonds along the third surface 103 include silicon face dangling bonds and carbon face dangling bonds. The auxiliary atoms 110 are of one or more nonmetal elements other than silicon and carbon and saturate the dangling bonds to a large extent. The nonmetal elements include hydrogen, nitrogen, oxygen, phosphorus, sulfur, selenium, the halogens (group 17 elements), and the noble gases (group 18 elements). According to an example, the nonmetal elements are selected from nitrogen, oxygen, and phosphorus.

The auxiliary atoms 110 render the dangling bonds electrically inactive, at least to a large extent, such that the dangling bonds affect the dielectric strength along the third surface 103 to only a negligible extent, if at all. For example, the auxiliary atoms 110 lower a density of interface states (Dit) along the third surface 103 to at most 5E12 1/cm²eV, at most 2E12 1/cm²eV or at most 1E12 1/cm²eV.

The edge structure 200 extends along the third surface 103 from the first surface 101 into the silicon carbide portion 100. The edge structure 200 includes a glass structure 250 and an interface layer structure 220 formed between the silicon carbide portion 100 and the glass structure 250.

In FIG. 1A the edge structure 200 further includes the passivating coating 210 between the silicon carbide portion 100 and the interface layer structure 220.

In FIG. 1B, the interface layer structure 220 is in direct contact with the silicon carbide portion 100, wherein the auxiliary atoms 110 are embedded along the interface between the silicon carbide portion 100 and the interface layer structure 220.

In a blocking mode of the semiconductor device 500, the edge structure 200 confines the rear side potential of the second metal structure 320 at the rear side. The lateral extension of a lateral termination structure can be reduced or such lateral termination structure may be completely omitted. The dangling bonds along the third surface 103 are saturated and/or passivated to a sufficient extent and/or metal atoms are absent to such an extent that the dielectric strength of the semiconductor device 500 is sufficiently high.

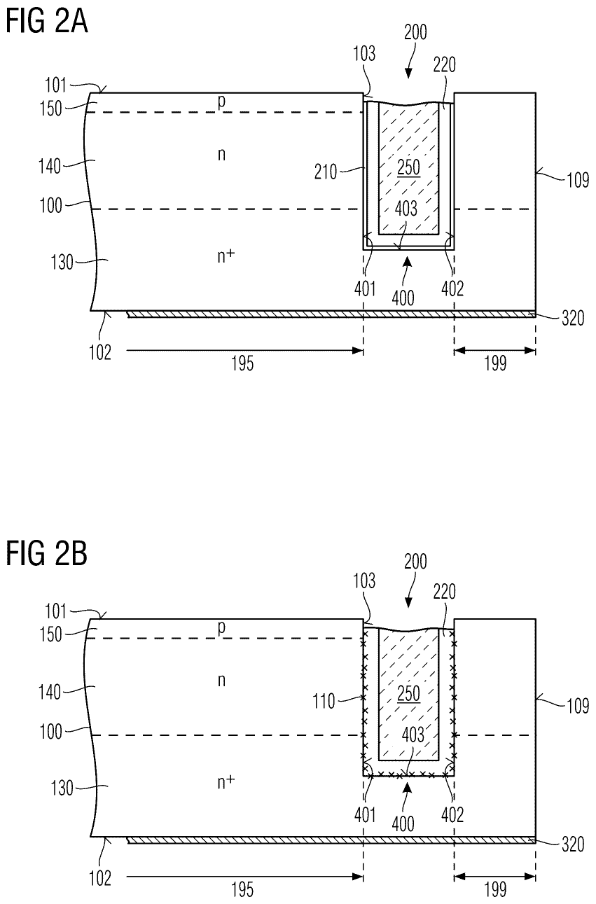

In FIG. 2A and FIG. 2B the third surface 103 is an inner sidewall of a trench structure 400 that separates a center portion 195 from a peripheral portion 199 of the silicon carbide portion 100.

The trench structure 400 laterally surrounds the center portion 195 of the silicon carbide portion 100. The peripheral portion 199 separates the trench structure 400 from the lateral surface 109 that connects the edge of the first surface 101 with the edge of the second surface 102. The trench structure 400 has a uniform vertical extent (“depth”) and a uniform lateral width between the center portion 195 and the peripheral portion 199. The trench structure 400 forms a continuous frame around the center portion 195. The frame may be rectangular with four orthogonal, straight sections. Along each straight section of the lateral surface 109, the trench structure 400 has a uniform lateral distance to the lateral surface 109. The body/anode region 150 is formed in the center portion 195 and is absent in the peripheral portion 199. Instead, the main layer 140 extends from the first surface 101 to the base portion 130 in the peripheral region 199.

In FIG. 2A, the passivating coating 210 is in direct contact with the complete inner sidewall 401 of the trench structure 400 oriented to the center portion 195. In addition, the passivating coating 210 is in direct contact with the outer sidewall 402 of the trench structure 400 and with the bottom 403 of the trench structure 400. The interface layer structure 220 covers all sections of the passivating coating 210. In the illustrated example, the interface layer structure 220 covers all sections of the passivating coating 210 with uniform thickness. The glass structure 250 completely fills the space between the various sections of the interface layer structure 220.

In FIG. 2B, the auxiliary atoms 110 saturate dangling bonds of the silicon carbide portion 100 along the inner sidewall 401 of the trench structure 400 oriented to the center portion 195. In addition, the auxiliary atoms 110 saturate dangling bonds of the silicon carbide portion 100 along an outer sidewall 402 of the trench structure 400 oriented to the peripheral portion 199 and/or along a bottom 403 of the trench structure 400 oriented to the second surface 102 and connecting the inner sidewall 401 with the outer sidewall 402. The interface layer structure 220 covers the inner sidewall 401, the outer sidewall 402, and the bottom 403. In the illustrated example, the interface layer structure 220 covers the inner sidewall 401, the outer sidewall 402, and the bottom 403 with uniform thickness. The glass structure 250 completely fills the space between the various sections of the interface layer structure 220.

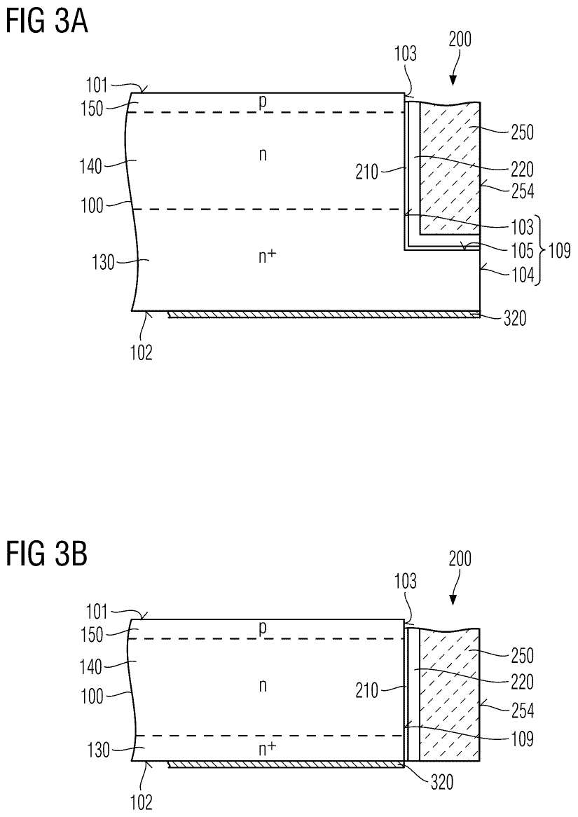

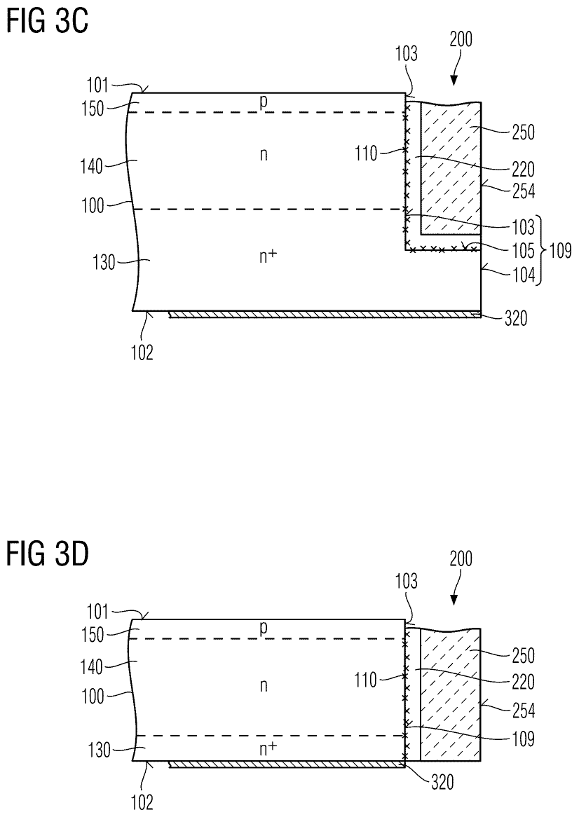

In FIG. 3A, FIG. 3B, FIG. 3C and FIG. 3D, the third surface 103 forms the lateral surface 109 or a portion of the lateral surface 109 connecting an edge of the first surface 101 and an edge of the second surface 102 of the silicon carbide portion 100.

In FIG. 3A and FIG. 3C, the lateral surface 109 includes the third surface 103 extending from the first surface 101 into direction of the second surface 102, a fourth surface 104 extending from the second surface 102 into direction of the first surface 101, and a fifth surface 105 connecting the neighboring edges of the third and fourth surfaces 103, 104 at a distance to the first and second surfaces 101, 102. The fourth surface 104 may extend vertically. The third surface 103 may extend vertically or may be tilted to the vertical direction by not more than 20 degrees. The fifth surface 105 may extend horizontally or may be tilted to the horizontal direction by not more than 20 degrees.

In FIG. 3A, a first section of the passivating coating 210 is in direct contact with the third surface 103. A second section of the passivating coating 210 is in direct contact with the fifth surface 105. The interface layer structure 220 covers the first and second sections of the passivating coating 210 with uniform thickness. The glass structure 250 is in direct contact with the interface layer structure 220. An outer lateral surface 254 of the glass structure 250 averted from the third surface 103, the fourth surface 104 of the silicon carbide portion 100, and lateral edges of the passivating coating 210 and the interface layer structure 220 are coplanar and form smooth transitions without bends and kinks.

In FIG. 3B the third surface 103 forms the lateral surface 109 that extends in the vertical direction from the edge of the first surface 101 to the edge of the second surface 102. The passivating coating 210 extends in the vertical direction from the first surface 101 to the second surface 102. The interface layer structure 220 extends in the vertical direction from the plane of the first surface 101 to the plane of the second surface 102. The glass structure 220 extends in the vertical direction from the plane of the first surface 101 to the plane of the second surface 102.

FIG. 3C shows auxiliary atoms 110 that saturate dangling bonds of the silicon carbide portion 100 along the third surface 103 to a large extent. In addition, auxiliary atoms 110 are present along the fifth surface 105. The interface layer structure 220 is formed directly on the third surface 103 and the fifth surface 105. The glass structure 250 is in direct contact with the interface layer structure 220. An outer lateral surface 254 of the glass structure 250, the lateral edge of the interface layer structure 220, and the fourth surface 104 of the silicon carbide portion 100 are coplanar.

In FIG. 3D the third surface 103 forms the lateral surface 109 that extends in the vertical direction from the edge of the first surface 101 to the edge of the second surface 102. Auxiliary atoms 110 saturate dangling bonds of the silicon carbide portion 100 along the third surface 103 to a large extent. The interface layer structure 220 extends in the vertical direction from the plane of the first surface 101 to the plane of the second surface 102. The glass structure 220 extends in the vertical direction from the plane of the first surface 101 to the plane of the second surface 102.

In all figures described up to this point, the interface layer structure 220 includes a trench portion in the volume between the first surface 101 and the second surface 102. The interface layer structure 220 may include only the trench portion, wherein the interface layer structure 220 is completely formed in the volume between the first surface 101 and the second surface 102.

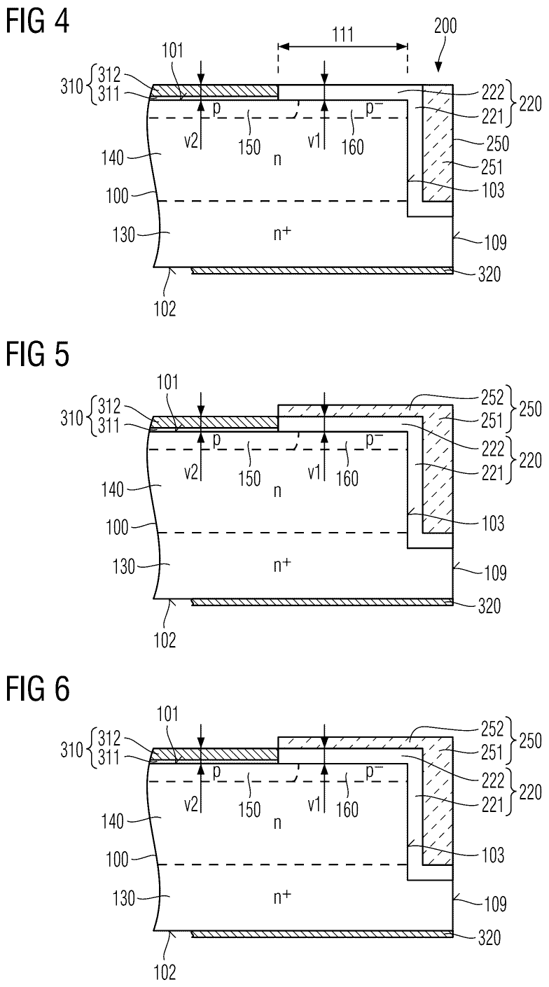

In FIG. 4, a field relaxing structure 160 of the second conductivity type laterally surrounds the body/anode region 150. A net doping of the field relaxing structure 160 is lower than a net doping of the body/anode region 150. For example, the net doping in the field relaxing structure 160 is at most 50% or at most 10% of the net doping in the body/anode region 150.

In the vertical direction, the field relaxing structure 160 is formed between the less heavily doped main layer 140 and the first surface 101. In the horizontal directions, the field relaxing structure 160 is formed between the body/anode region 150 and a trench portion 221 of the interface layer structure 220. In the illustrated example, the field relaxing structure 160 extends from the first surface 101 to the main layer 140, and from the body/anode region 150 to the trench portion 221 of the interface layer structure 220. In another example, the field relaxing structure 160 may be in direct contact with a passivating coating 210 as illustrated in FIG. 1A.

FIG. 4 further shows an edge structure 200 whose interface layer structure 220 includes a trench portion 221 formed between the first surface 101 and the second surface 102, and a surface portion 222 formed on the first surface 101. The trench portion 221 and the surface portion 222 are connected to each other and form a continuous, one-part structure. The trench portion 221 and the surface portion 222 are layered portions that may have the same thickness. At least the surface portion 222 covering an edge region 111 of the first surface 101 directly along an edge or transition between the first surface 101 and the third surface 103 has a first vertical extent v1.

The field relaxing structure 160 is completely formed in the edge region 111. The surface portion 222 of the interface layer structure 200 is in direct contact with the field relaxing structure 160 across the complete width of the field relaxing structure 160 and laterally overlaps with the body/anode region 150.

A first metal structure 310 is formed on a front side of the silicon carbide portion 100 on a portion of the first surface 101 surrounded by the surface portion 222 of the interface layer structure 200. In the lateral directions, the first metal structure 310 is in direct contact with the interface layer structure 220, wherein the surface portion 222 of the interface layer structure 200 ends at the first metal structure 310 and the first metal structure 310 ends at the surface portion 222.

The first metal structure 310 and the surface portion 222 of the interface layer structure 220 form an interface including a single surface tilted to the first surface 101. No lateral overlap exists between the surface potion 222 and the first metal structure 310.

A first vertical extent v1 of the surface portion 222 of the interface layer structure 220 is at least 80% and at most 120% of a second vertical extent v2 of the first metal structure 310. In the illustrated example, the first vertical extent v1 and the second vertical extent v2 are equal.

The first metal structure 310 may include a contact layer 311 formed directly on the first surface 101 and a principal layer 312 formed directly on the contact layer 311.

The contact layer 311 and doped regions in the silicon carbide portion 100 form electric contacts, e.g., low-resistive ohmic contacts and/or Schottky contacts. For example, the first metal structure 310 contains metal atoms forming a stable, high-conductive phase with silicon and carbon. The principal layer 312 contains aluminum and/or copper, e.g., an aluminum copper alloy.

In the edge region 111 of the first surface 101, auxiliary atoms of hydrogen and/or one or more nonmetal elements other than silicon and having an atomic number greater than six saturate dangling bonds of the silicon carbide portion 100 to a large extent. Alternatively or in addition, a dense passivating coating may be in direct contact with the silicon carbide portion 100 in the edge region 111 of the first surface 101.

For the illustrated example, no passivating coating 210 is formed on the first surface 101 in the edge region 111, and the interface layer structure 220 is in direct contact with the first surface 101 in the edge region 111.

The glass structure 250 of the edge structure 200 includes a trench part 251 in the volume between the interface layer structure 220 and the lateral edge of the semiconductor device. In the illustrated example, the glass structure 250 includes only the trench part 251 and is completely formed in the volume between the interface layer structure 220 and the lateral edge of the semiconductor device.

FIG. 5 shows an edge structure 200 whose glass structure 250 includes a horizontal part 252 formed on the interface layer structure 220.

The glass structure 250 includes the horizontal part 252 in addition to a trench part 251 formed in the volume between the interface layer structure 220 and the lateral edge of the semiconductor device. More particularly, a first portion of the horizontal part 252 is formed directly on the surface portion 222 of the interface layer structure 220 and a second portion of the horizontal part 252 is formed directly on the trench part 251 of the glass structure 250. The horizontal part 252 and the trench part 251 are connected to each other and form a continuous one-part structure with an L-shaped vertical cross-section. The horizontal part 252 covers at least a section of the surface portion 222 of the interface layer structure 220 directly adjacent to the trench portion 221.

In FIG. 5, the horizontal part 252 of the glass structure 250 covers the surface portion 222 of the interface layer structure 220 completely and laterally overlaps an outer portion of the body/anode region 150.

In FIG. 6, the horizontal part 252 covers only an inner section of the surface portion 222 of the interface layer structure 220 directly adjacent to the trench part 252 and is absent on an outer section averted from the trench part 252. The horizontal part 252 does not overlap the body/anode region 150.

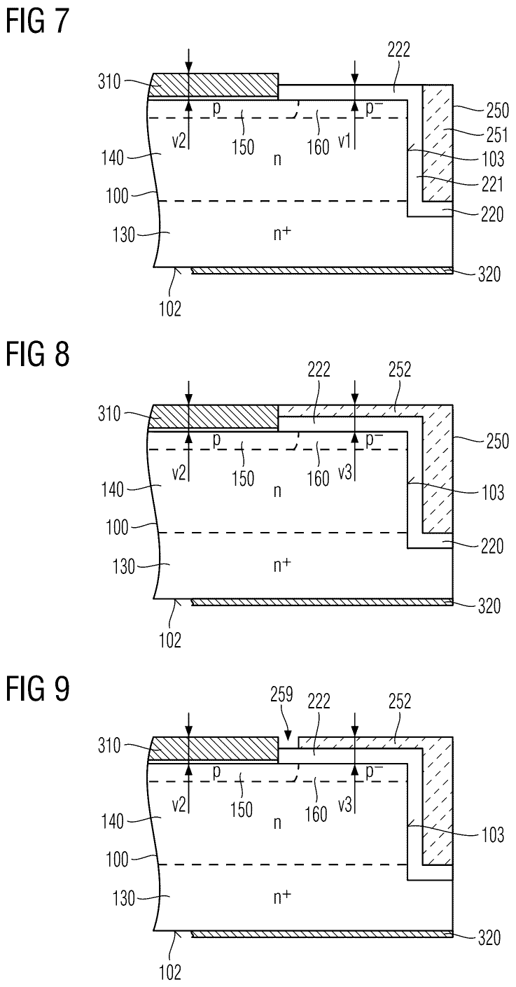

FIG. 7 shows a semiconductor device in which the surface portion 222 of the interface layer structure 220 has a first vertical extent v1 that is less than 80% of a second vertical extent v2 of the first metal structure 310.

According to another example, the first vertical extent v1 of the surface portion 222 of the interface layer structure 220 is at most 60% or 50% of the second vertical extent v2 of the first metal structure 310.

The glass structure 250 includes only the trench part 251, wherein an upper surface of the trench part 251 and a top surface of the surface portion 222 of the interface layer structure 220 are essentially coplanar.

In FIG. 8, the surface portion 222 of the interface layer structure 220 has a first vertical extent v1 that is less than 80% of the second vertical extent v2 of the first metal structure 320. The glass structure 220 includes a horizontal part 252 in lateral contact with the first metal structure 310. A total thickness v3 of the interface layer structure 220 and the horizontal part 252 of the glass structure 250 and the second vertical extent v2 of the first metal structure 310 are essentially equal. Top surfaces of the glass structure 250 and the first metal structure 310 averted from the silicon carbide portion 100 are essentially in the same plane. The glass structure 250 and the first metal structure 310 form an interface tilted to the first surface 101.

FIG. 9 shows an auxiliary gap 259 between the first metal structure 310 and the horizontal part 252 of the glass structure 250. The auxiliary gap 259 exposes a top surface of the interface layer structure 220 and laterally separates the glass structure 250 from the first metal structure 310.

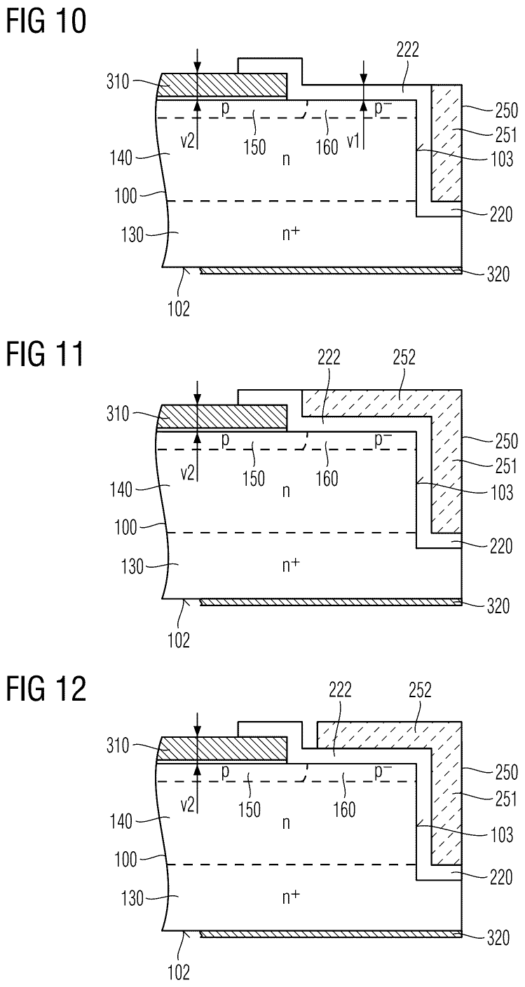

FIG. 10, FIG. 11 and FIG. 12 show surface portions 222 of the interface layer structure 220 laterally overlapping the first metal structure 310.

Each of the surface portions 222 includes a step and covers both a lateral surface of the first metal structure 310 oriented to the interface layer structure 220 and a peripheral portion of the first metal structure 310 directly along the lateral edge of the first metal structure 310.

A first portion of the surface portion 220 of the interface layer structure 220 is in direct contact with the first surface 101 of the silicon carbide portion 100. A second portion of the surface portion 220 of the interface layer structure 220 is in direct contact with a section of the top surface of the first metal structure 310.

In FIG. 10, a top surface of the glass structure 250 and a top surface of the first portion of the surface portion 220 of the interface layer structure 220 are essentially coplanar.

In FIG. 11 and FIG. 12, the top surface of the glass structure 250 and a top surface of the second portion of the surface portion 222 of the interface layer structure 220 are essentially coplanar.

In FIG. 11, a lateral end face of the horizontal part 252 of the glass structure 250 is in direct contact with a vertical section of the surface portion 222 of the interface layer structure 220 along the step.

In FIG. 12, a separation gap 258 exposes a section of the first portion of the surface portion 222 and laterally separates the horizontal part 252 of the glass structure 250 from the second portion of the surface portion 222. The lateral end face of the horizontal part 252 of the glass structure 250 is laterally separated from the vertical section of the surface portion 222 of the interface layer structure 220.

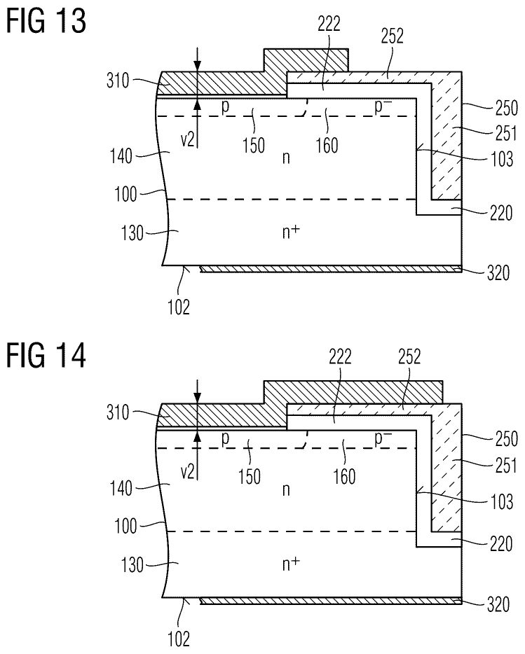

FIG. 13 and FIG. 14 show the first metal structure 310 laterally overlapping the glass structure 250.

The first metal structure 310 includes a step and covers both a lateral surface of the glass structure 250 oriented to the first metal structure 310 and a peripheral portion of the glass structure 250 directly along the edge of the glass structure 250.

In FIG. 13, the first metal structure 310 only partially overlaps the field relaxing structure 160.

In FIG. 14, the first metal structure 310 overlaps the field relaxing structure 160 completely and a lateral edge of the first metal structure 310 is directly above the trench part 251 of the glass structure 250.

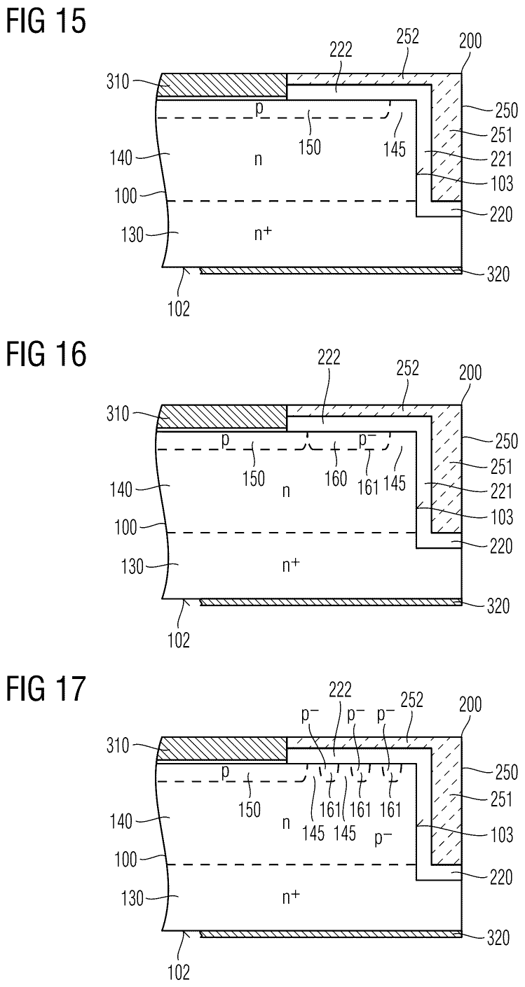

FIG. 15 shows a separation region 145 of the first conductivity type extending along the edge structure 200 from the first surface 101 to the main layer 140. The separation region 145 laterally separates the body/anode region 150 from the edge structure 200.

FIG. 16 shows a field relaxing structure 160 extending form the first surface 101 to the main layer 140, and between the body/anode region 150 and the trench portion 221 of the interface layer structure 220. The field relaxing structure 160 laterally surrounds the body/anode region 150. The field relaxing structure 160 may laterally adjoin to the body/anode region 150 or may have a lateral end region where doping concentration profiles of the field relaxing structure 160 and the body/anode region 150 overlap. A net doping in the field relaxing structure 160 is lower than a net doping in the body/anode region 150. For example, the net doping in the field relaxing structure 160 is at most 50% of the net doping in the body/anode region 150. The field relaxing structure 160 and the body/anode region 150 form a unipolar junction. A separation region 145 of the first conductivity type extends along the edge structure 200 from the first surface 101 to the main layer 140 and laterally separates the field relaxing structure 160 from the edge structure 200.

The field relaxing structure 160 includes one single field relaxing ring 161, wherein the field relaxing ring 161 and the body/anode region 150 form a unipolar junction. A net doping in the field relaxing ring 161 is in a range from 5E16 to 5E18 cm⁻³, 1E17 to 1E18 cm⁻³ or 1E17 to 5E17 cm⁻³.

In FIG. 17, the field relaxing structure 160 includes a plurality of laterally separated field relaxing rings 161. Separation regions 145 of the first conductivity type extend between neighboring field relaxing rings 161 and between an innermost field relaxing ring 161 and the body/anode region 150 from the first surface 101 to the main layer 140.

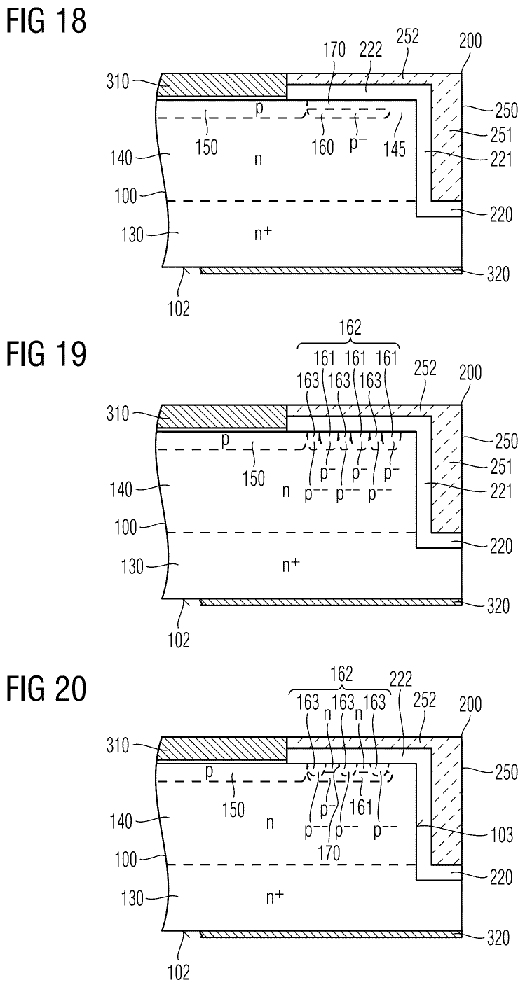

FIG. 18 shows a surface layer 170 of the first conductivity type between the first surface 101 and the field relaxing structure 160. The surface layer 170 separates the field relaxing structure 160 from the first surface 101. The field relaxing structure 160 includes one single field relaxing ring 161 as illustrated or a plurality of laterally separated field relaxing rings 161. The field relaxing structure 160 may laterally adjoin to the body/anode region 150 or may have a lateral end region where doping concentration profiles of the field relaxing structure 160 and the body/anode region 150 overlap.

In FIG. 19 and FIG. 20, the field relaxing structure 160 includes a supplementary structure 162 having the second conductivity type and a lower net doping than the field relaxing rings 161. A net doping in the supplementary structure 162 is in a range from 1E17 to 5E17 cm⁻³ and can be combined with a net doping in the field relaxing ring 161 in a range from 1E18 to 1E19 cm⁻³.

In FIG. 19, the supplementary structure 162 includes a plurality of supplementary rings 163, wherein each supplementary ring 163 is formed between two neighboring field relaxing rings 161, or between an innermost field relaxing ring 161 and the body/anode region 150. The supplementary rings 163 extend from the first surface 101 to the main layer 140 and laterally separate the field relaxing rings 161.

In FIG. 20, a surface layer 170 of the first conductivity type is formed between the first surface 101 and a single field relaxing ring 161, and a plurality of laterally separated supplementary rings 163 extend from the first surface 101 through the surface layer 170 into the field relaxing ring 161. The field relaxing ring 161 may laterally adjoin to the body/anode region 150 or may have a lateral end region where doping concentration profiles of the field relaxing ring 161 and the body/anode region 150 overlap.

The field relaxing structures 160, field relaxing rings 161, supplementary structures 162, supplementary rings 163 and the surface layer 170 form a lateral field termination structure that shapes the electric field in the portion of the silicon carbide layer close to the edge structure 200 in a way that the maximum electric field in the edge structure 200 is significantly reduced and the breakdown voltage significantly increased. The width of the lateral field termination structure is less than 50%, e.g. less than 20% of a lateral width of conventional lateral field termination structure without edge structure 200.

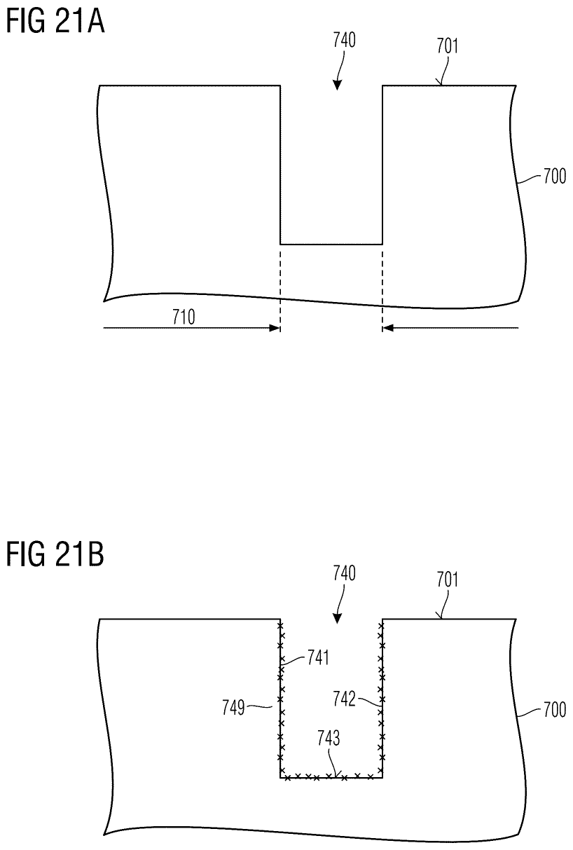

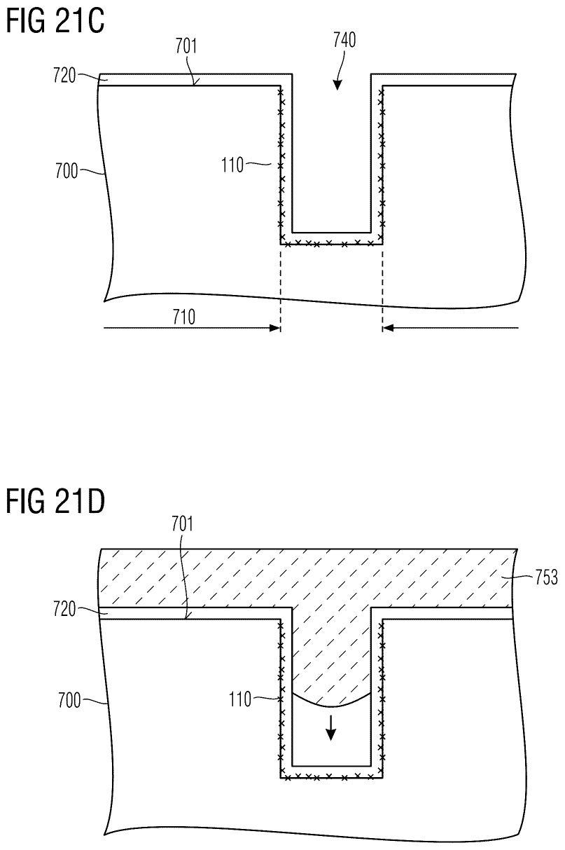

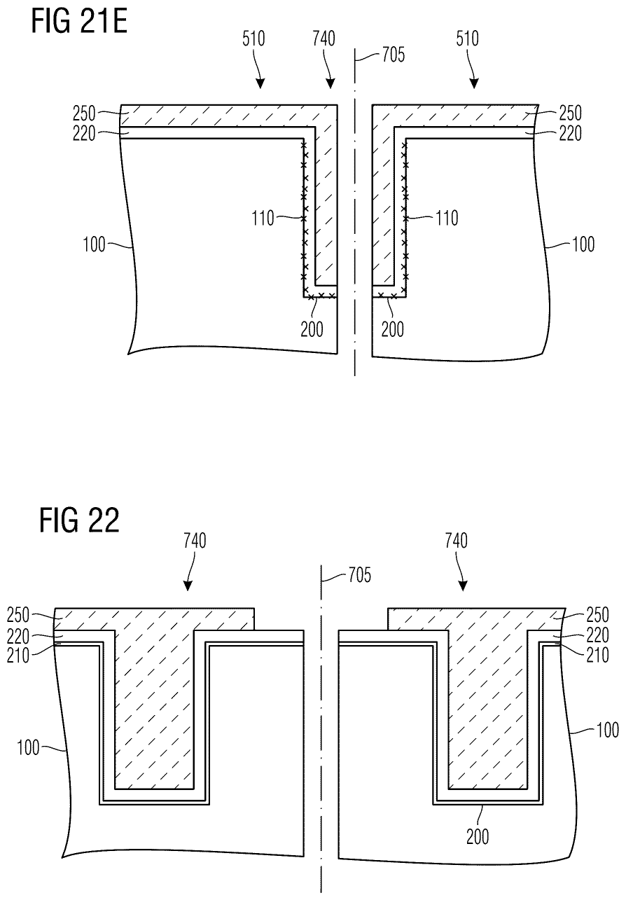

The methods described in the following with reference to FIG. 21A to FIG. 29C can be used to obtain the semiconductor devices described with reference to FIG. 1A to FIG. 20, and the semiconductor devices described with reference to FIG. 1A to FIG. 20 can be obtained with any suitable method described with reference to FIG. 21A to FIG. 29C.

FIG. 21A to FIG. 21E show vertical cross-sectional views of a part of a silicon carbide layer 700 for illustrating a method of manufacturing a semiconductor device.

According to FIG. 21A, a separation trench 740 is formed in a main surface 701 of a single-crystalline silicon carbide layer 700, wherein the separation trench 740 surrounds a die portion 710 of the silicon carbide layer 700.

The silicon carbide layer 700 may be a homogenous silicon carbide wafer or may be a layer formed on an underlayer of a material different from single-crystalline silicon carbide. The silicon carbide layer 700 may be uniformly doped. For example, the silicon carbide layer 700 is n doped.

The main surface 701 is at a frontside of the silicon carbide layer 700. The main surface 701 has a lateral extent in two orthogonal horizontal directions defined by an x axis and a y axis. A surface normal to the main surface 701 defines a vertical direction along a z axis.

Before or after forming the separation trench 740, further trenches, e.g., gate trenches may be formed that extend from the first main surface 701 into the silicon carbide layer 700.

Sidewalls of the separation trench 740 are inclined with respect to the main surface 701 by an angle in a range from 70 degrees to 110 degrees. The separation trench 740 ends within the silicon carbide layer 710.

At least a first sidewall 741 of the separation trench 740 is treated in a conditioning process, wherein dangling bonds of the silicon carbide layer 700 along the first sidewall 741 are made inactive.

The dangling bonds along the third surface 103 include silicon face dangling bonds and carbon face dangling bonds. Passivating the dangling bonds may include a treatment providing auxiliary atoms 110 of hydrogen and/or one or more further nonmetal elements other than silicon and carbon to saturate (terminate) the dangling bonds to a large extent. The nonmetals include hydrogen, nitrogen, oxygen, phosphorous, sulfur, selenium, the halogens, and the noble gases. For example, the treatment may include a plasma-based flash passivation using oxygen gas O₂. Alternatively or in addition, passivating the dangling bonds may include depositing a dense passivation coating. Depositing the passivation coating may include forming a stack of dense conformal atomic layers on the first sidewall 741.

In both alternatives and, the dangling bonds are rendered electrically inactive at least to a large extent. After the treatment, a density of interface states (Dit) along the third surface 103 is at most 5E12 1/cm²eV, at most 2E12 1/cm²eV or at most 1E12 1/cm²eV.

In the illustrated example, the conditioning process is effective for the first sidewall 741 of the separation trench 740, the second sidewall 742, and the bottom 743 of the separation trench 740. The passivation makes the dangling bonds electrically inactive.

FIG. 21B shows passivated dangling bonds 749 along the first sidewall 741, the second sidewall 742 and the bottom 743 of the separation trench 740.

An interface layer 720 is deposited on the front side of the silicon carbide layer 700. The interface layer 720 may include at least one silicon oxide layer and/or one silicon nitride layer.

According to FIG. 21C, the interface layer 720 covers the main surface 701, the first sidewall 741 of the separation trench 740, the second sidewall 742 of the separation trench 740, and the bottom 743 of the separation trench 740.

A glass material 753 is placed or deposited on the interface layer 720. Initially, the glass material 753 may be solid. The glass material 753 is heated to a high temperature (e.g. above 200° C., or above 400° C. or even above 500° C.) and the glass material 753 is subjected to a pressure. Depending on the temperature, the pressure is selected such that at least a portion of the glass material 753 is liquified. The liquified portion of the glass material gradually fills the separation trench 740 as illustrated in FIG. 21D.

After the separation trench is filled (e.g., filled completely), the temperature and the pressure are reduced and the glass material 753 re-solidifies. The re-solidified glass material obtained in the glass embossing process may be patterned, e.g. by a polishing process, to form a glass fill structure.

The silicon carbide layer 700 is diced into a plurality of semiconductor dies 510 along vertical separation lines 705 that form a regular grid. Parallel to each vertical separation line 705 runs one separation trench 740 or a pair of separation trenches 740. The dicing may include mechanical sawing, by way of example.

FIG. 21E shows dicing along a vertical separation line 705 extending through and parallel to the separation trench 740 of FIG. 21D. The silicon carbide layer 700 of FIG. 21D is split into a plurality of silicon carbide portions 100. The interface layer 720 of FIG. 21D and the glass fill structure are split into edge structures 200, wherein each edge structure 200 includes an interface layer structure 220 formed from a portion of the interface layer 720 of FIG. 21E and a glass structure 250 formed from a portion of the glass fill structure.

FIG. 22 shows the dicing along a vertical separation line 705 extending between two parallel separation trenches 740 of FIG. 21D.

FIG. 23 shows a plan view on a silicon carbide layer 700 with separation trenches 740 forming a regular orthogonal grid and with vertical separation lines 705 running along the lateral center lines of the separation trenches 740.

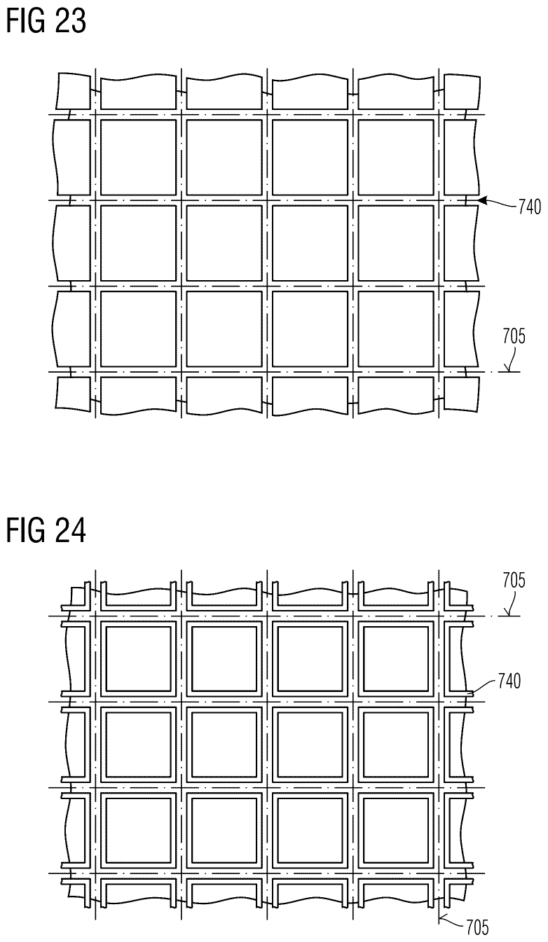

FIG. 24 shows a plan view on a silicon carbide layer 700 with each separation trench 740 forming a rectangular frame and with the rectangular frames arranged matrix-like in rows and columns. The vertical separation lines 705 run between neighboring frames.

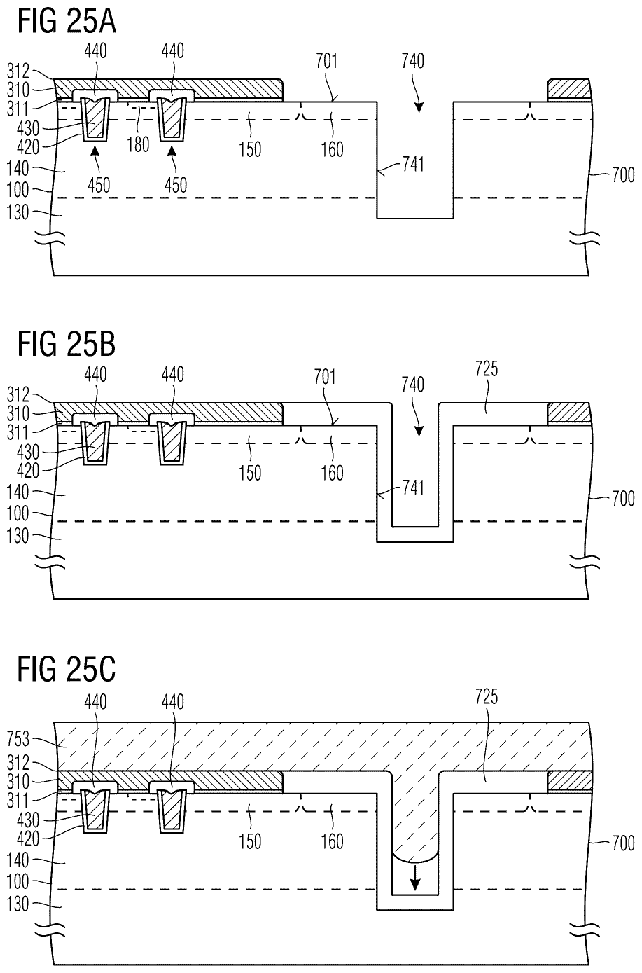

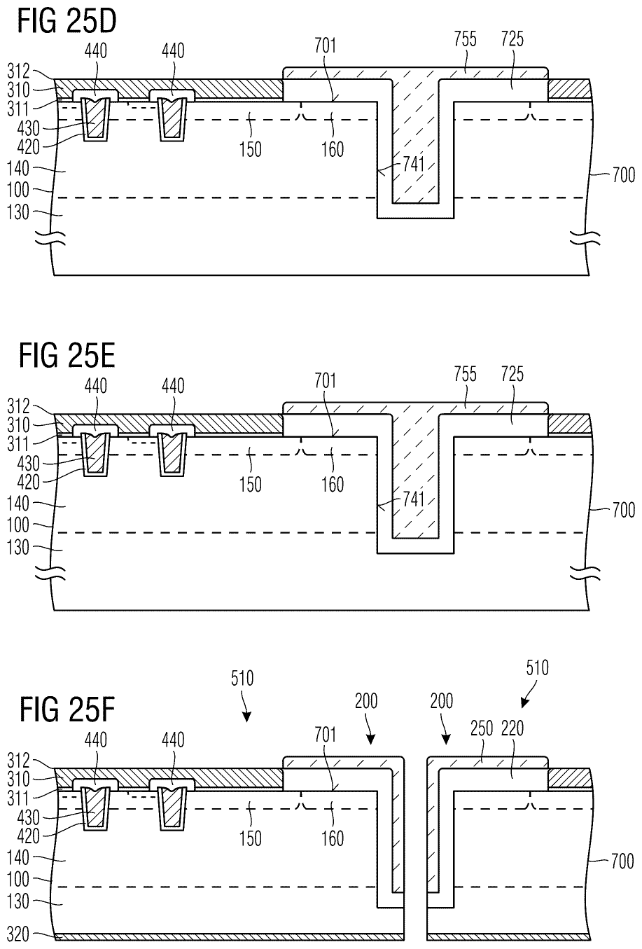

The methods described in the following with reference to FIG. 25A to FIG. 29C show a one-part field relaxing structure 160 as an example for a lateral field termination structure. The methods may be combined with any other lateral field termination structure, e.g., with any of the lateral field termination structures illustrated in FIG. to FIG. 20.

FIG. 25A to 25F refer to a method that includes forming the separation trench 740 after forming a first metal structure 310 on the main surface 701.

Gate trenches 450 extending from the main surface 701 into the silicon carbide layer 700 are formed. A gate dielectric 420 is formed on at least one sidewall of each gate trench 450. A gate electrode material, e.g. heavily doped polycrystalline silicon, is deposited and patterned to form gate electrodes 430 in the gate trenches 450. An interlayer dielectric 440 is formed that covers the gate electrodes 430 and exposes contact sections of the main surface 701 between the gate trenches 450. Source regions 180 of the first conductivity type are formed in the silicon carbide layer 700, wherein each source region 180 extends along at least one sidewall of a gate trench 450 from the main surface 701 into the body/anode region 150.

A contact layer 311 is formed on the contact sections of the main surface 701 and the interlayer dielectric 440. The contact layer 311 and the silicon carbide layer 700 form an ohmic contact. In additional or alternative examples, a Schottky contact may be formed between the contact layer 311 and the silicon carbide layer 700. A principal layer 312 is formed on the contact layer 311. The principal layer 312 includes at least one of aluminum (Al) and copper (Cu).

The principal layer 312 and the contact layer 311 are removed from a grid-shaped edge-and-kerf region of the main surface 701. A grid-shaped separation trench 740 is formed in the edge-and-kerf region.

FIG. 25A shows a first metal structure 310 including the patterned contact layer 311 and the patterned principal layer 312. The first metal structure 310 is absent in an edge region on both sides of the separation trench 740.

The sidewalls of the separation trench 740 are conditioned to saturate/passivate dangling bonds and/or remove metal atoms. An interface layer is deposited and portions of the interface layer deposited on the first metal structure 310 are removed.

FIG. 25B shows the patterned interface layer 725 covering the exposed portion of the main surface 701 in the edge region on both sides of the separation trench 740.

FIG. 25C shows a glass embossing process pressing glass material 753 in the separation trench 740. A portion of the resulting glass structure is removed from above the first metal structure 310.

FIG. 25D shows a glass fill structure 755 obtained by removal of glass from above the first metal structure 310. Edges of the patterned glass structure may be rounded.

FIG. 25E shows the glass fill structure 755 with rounded edges. The silicon carbide layer 700 is thinned, e.g. ground, from the rear side. The thinning stops at a vertical distance to the bottom of the separation trench 740. A second metal structure 320 is formed on the rear side after thinning. The silicon carbide layer is divided into semiconductor dies 510 along vertical separation lines running along horizontal longitudinal axes of the separation trenches 740.

FIG. 25F shows two semiconductor dies 510, each of them with an edge structure 200 that includes a portion of the patterned interface layer 725 and a portion of the glass fill structure 755 with rounded edges of FIG. 25E.

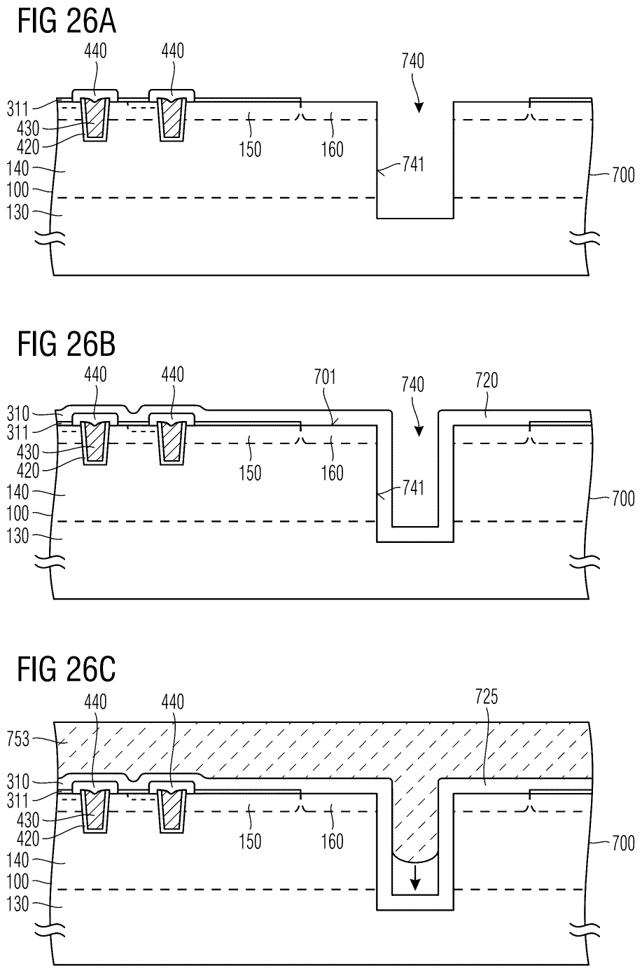

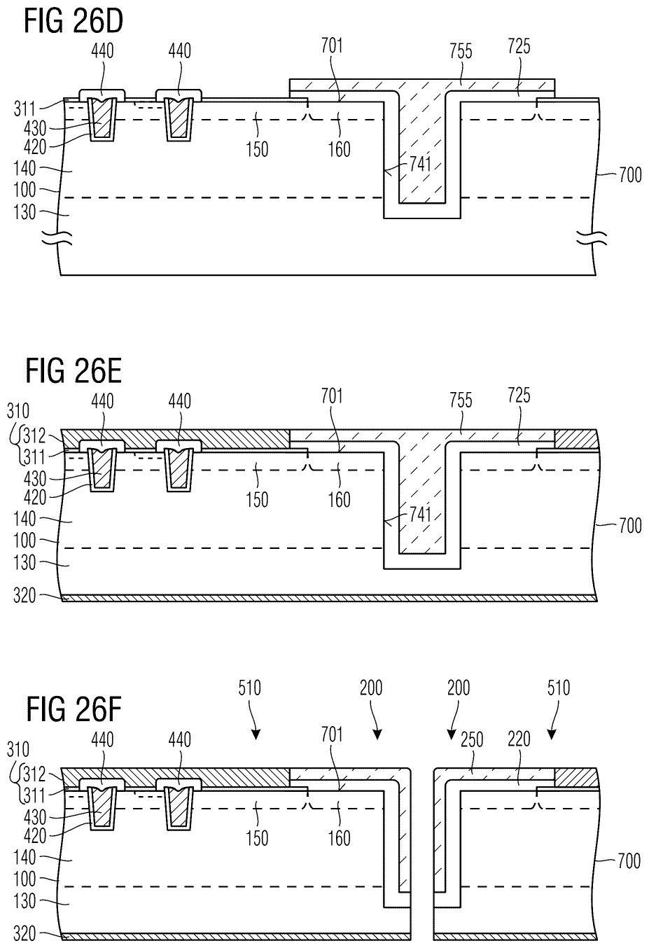

FIG. 26A to 26F show a method that includes forming the separation trench 740 after forming gate electrodes 430 and before depositing the principal layer 320.

Gate electrodes 430 are arranged in gate trenches 450. An interlayer dielectric 440 is formed that covers the gate electrodes 430 and exposes contact sections of the main surface 701 between the gate trenches 450. A contact layer 311 is formed on the contact sections of the main surface 701 and the interlayer dielectric 440. The contact layer 311 and the silicon carbide layer 700 form ohmic contacts. Separately or in combination, the contact layer 311 and the silicon carbide layer 700 may form a Schottky contact. A portion of the contact layer 311 in a grid-shaped edge-and-kerf region of the main surface 701 is removed. A grid-shaped separation trench 740 is formed in the edge-and-kerf region.

FIG. 26A shows the patterned contact layer 311 on the contact sections of the main surface between laterally separated sections of the interlayer dielectric 440. The contact layer 311 is absent in an edge region on both sides of the separation trench 740 above the field relaxing structure 160.

The sidewalls of the separation trench 740 are conditioned to saturate/passivate dangling bonds and/or remove metal atoms. An interface layer 720 is deposited.

FIG. 26B shows the interface layer 720 covering the exposed portion of the main surface 701 in the edge region on both sides of the separation trench 740, the interlayer dielectric 440 and the contact layer 311.

FIG. 26C shows a glass embossing process pressing glass material 753 in the separation trench 740. Portions of the resulting glass structure and the interface layer 720 are removed from above the interlayer dielectric 440 and the contact layer 311. The silicon carbide layer is thinned, e.g. ground, from the rear side. The thinning stops at a vertical distance to the bottom of the separation trench 740. A second metal structure 320 is formed on the rear side after thinning.

FIG. 26D shows a glass fill structure 755 and a patterned interface layer 725 obtained by removal of glass from above the interlayer dielectric 440 and the contact layer 311.

A principal layer 312 is formed on the contact layer 311 and the interlayer dielectric 440. The principal layer 312 includes at least one of aluminum (Al) and copper (Cu). The contact layer 311 and/or the principal layer 312 may be formed before or after the thinning process (e.g. the grinding process).

As shown in FIG. 26E, top surfaces of the principal layer 312 and glass fill structure 755 may be essentially coplanar.

The silicon carbide layer 700 is divided into semiconductor dies 510 along vertical separation lines running along horizontal longitudinal axes of the separation trenches 740.

FIG. 26F shows two semiconductor dies 510, each of them with an edge structure 200 that includes a portion of the patterned interface layer 725 and a portion of the glass fill structure 755 with rounded edges of FIG. 25E.

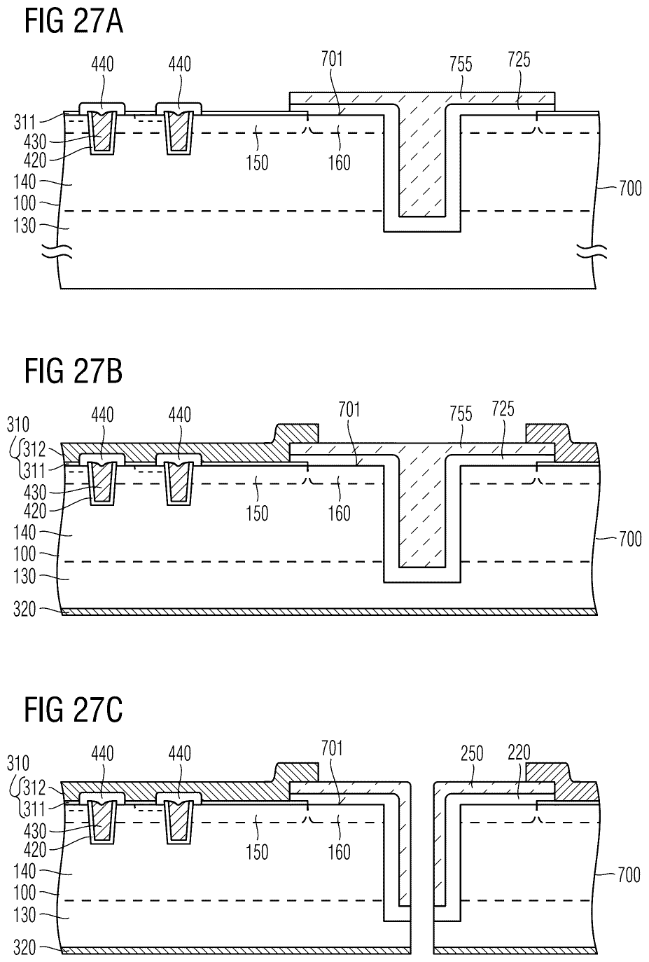

The process sequence illustrated in FIG. 27A to 27C differs from the process sequence illustrated in FIG. 26D to 26F in that the principal layer 312 is formed to cover an outer section of the glass fill structure 755. Principal layer 312 and glass fill structure 755 laterally overlap.

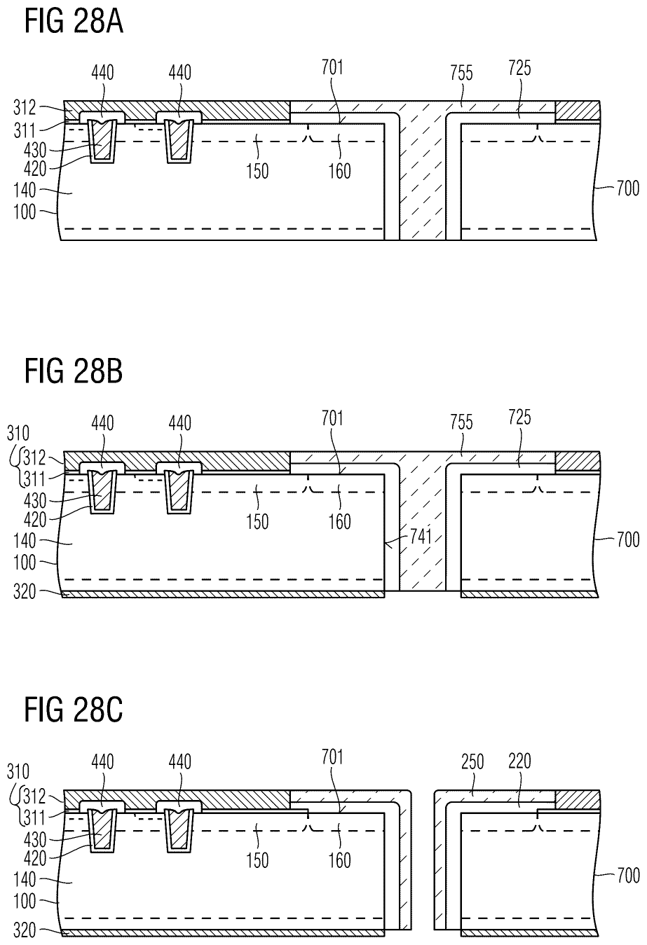

The process sequence illustrated in FIG. 28A to 28C differs from the process sequence illustrated in FIG. 26D to 26F in that the thinning stops after exposure of the glass fill structure 755. The method may be combined with the semiconductor devices shown in FIG. 3B and FIG. 3D.

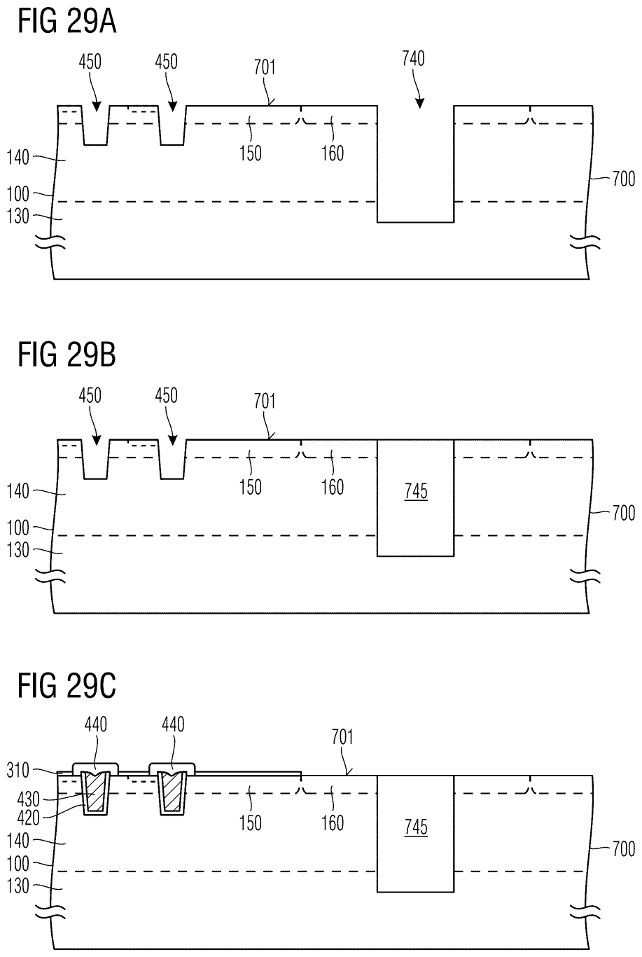

According to FIG. 29A, the gate trenches 450 and the separation trench 740 are formed simultaneously using the same mask or in directly consecutive mask and etch processes. The separation trench 740 may be formed before forming the gate trenches 450. In other examples, the separation trench 740 may be formed after forming the gate trenches 450. A sidewall conditioning for passivating dangling bonds and/or removing metal atoms is performed that is effective for both the gate trenches 450 and the separation trench.

FIG. 29A shows the gate trenches 450 and the separation trench 740 extending from the main surface 701 into the silicon carbide layer 700. The separation trench 740 is filled with a sacrificial material 745.

FIG. 29B shows the separation trench 740 filled with the sacrificial material 745. The process proceeds with forming the gate dielectric 420, the gate electrode 430 and the interlayer dielectric 440.

FIG. 29C shows the gate dielectric 420, the gate electrode 430 and the interlayer dielectric 440. In a later process step (not shown in FIG. 29C), the sacrificial material 745 is removed and, afterwards, the interface layer 725 is deposited.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a single-crystalline silicon carbide portion comprising a first surface, an opposite second surface, and a third surface extending from the first surface in a direction of the second surface, wherein a) along the third surface, hydrogen atoms and/or atoms of one or more nonmetal elements other than silicon and having an atomic number greater than six saturate dangling bonds of the silicon carbide portion and/or b) a passivating coating is in direct contact with the third surface;
a glass structure; and
an interface layer structure between the third surface and the glass structure.

2. The semiconductor device of claim 1,
wherein the one or more nonmetal elements include at least one of nitrogen, oxygen, and phosphorus.

3. The semiconductor device of claim 1,
wherein the passivating coating comprises a layer structure that includes at least one of: an oxide layer; a nitride layer; an oxynitride layer; and a carbon-containing layer.

4. The semiconductor device of claim 1,
wherein the third surface includes an inner sidewall of a trench structure laterally surrounding a center portion of the silicon carbide portion.

5. The semiconductor device of claim 1,
wherein the third surface forms at least a portion of a lateral surface connecting an edge of the first surface and an edge of the second surface.

6. The semiconductor device of claim 5,
wherein the third surface connects the edge of the first surface and the edge of the second surface.

7. The semiconductor device of claim 1,
wherein the silicon carbide portion includes a heavily doped base portion of a first conductivity type and a less heavily doped main layer of the first conductivity type between the first surface and the base portion, and
wherein the third surface laterally exposes the main layer and the base portion.

8. The semiconductor device of claim 1,
wherein the interface layer structure comprises a surface portion on the first surface.

9. The semiconductor device of claim 8,
wherein the glass structure comprises a horizontal part formed on the interface layer structure.

10. The semiconductor device of claim 9, further comprising:
a first metal structure in direct contact with the first surface of the silicon carbide portion and the interface layer structure.

11. The semiconductor device of claim 10,
wherein a first vertical extent of the surface portion of the interface layer structure is at least 80% and at most 120% of a second vertical extent of the first metal structure.

12. The semiconductor device of claim 10,
wherein a first vertical extent of the surface portion of the interface layer structure is less than 80% of a second vertical extent of the first metal structure.

13. The semiconductor device of claim 12,
wherein a total thickness of the interface layer structure and the horizontal part of the glass structure and the second vertical extent of the first metal structure are equal.

14. The semiconductor device of claim 13,
wherein the first metal structure and the horizontal part of the glass structure are laterally separated.

15. The semiconductor device of claim 10,
wherein in a lateral direction, the surface portion of the interface layer structure ends at the first metal structure and the first metal structure ends at the surface portion of the interface layer structure.

16. The semiconductor device of claim 10,
wherein the surface portion of the interface layer structure and the first metal structure overlap in the vertical direction.

17. The semiconductor device of claim 16, further comprising:
a body/anode region of a second conductivity type complementary to the first conductivity type,
wherein the silicon carbide portion includes a heavily doped base portion of a first conductivity type and a less heavily doped main layer of the first conductivity type between the first surface and the base portion,
wherein the third surface laterally exposes the main layer and the base portion, and
wherein the body/anode region is formed between the main layer and the first surface.

18. The semiconductor device of claim 17,
wherein the body/anode region is formed at a distance to the interface layer structure and the passivating coating.

19. The semiconductor device of claim 17, further comprising:
a field relaxing structure of the second conductivity type laterally surrounding the body/anode region,
wherein a net doping of the field relaxing structure is lower than a net doping in the body/anode region.

20. The semiconductor device of claim 19,
wherein the field relaxing structure is in direct contact with the interface layer structure or the passivating coating.

21. The semiconductor device of claim 19,
wherein the field relaxing structure is formed at a distance to the interface layer structure and the passivating coating.

22. The semiconductor device of claim 19,
wherein the field relaxing structure comprises a single field relaxing ring.

23. The semiconductor device of claim 19,
wherein the field relaxing structure comprises a plurality of laterally separated field relaxing rings.

24. The semiconductor device of claim 19, further comprising:
a surface layer of the first conductivity type between the first surface and the field relaxing structure.

25. The semiconductor device of claim 19,
wherein the field relaxing structure comprises a plurality of field relaxing rings and a supplementary structure, and
wherein the supplementary structure is in direct contact with the field relaxing rings and has a lower net doping than the field relaxing rings.

26. The semiconductor device of claim 25,
wherein the supplementary structure comprises a plurality of supplementary rings, each supplementary ring formed between neighboring ones of the field relaxing rings or between an innermost one of the field relaxing rings and the body/anode region.

27. A method of manufacturing a semiconductor device, the method comprising:
forming a separation trench in a main surface of a single-crystalline silicon carbide layer, wherein the separation trench surrounds a die portion of the silicon carbide layer;
treating a first sidewall of the separation trench in a conditioning process such that dangling bonds of the silicon carbide layer are passivated;
forming an interface layer on the first sidewall of the separation trench;
forming a glass fill structure in the separation trench; and
separating the silicon carbide layer along a vertical separation line parallel to the separation trench.

28. The method of claim 27,
wherein the vertical separation line runs through and along the separation trench.

29. The method of claim 27,
wherein treating the first sidewall of the separation trench comprises a plasma-based flash passivation.

30. The method of claim 27,
wherein treating the first sidewall of the separation trench comprises depositing a passivation coating using a precursor material containing silicon as a main component.

31. The method of claim 27,
wherein forming the glass fill structure comprises pressing a glass material into the separation trench.

32. The method of claim 27, further comprising:
forming a contact layer in a contact section of the main surface, wherein the contact layer and the silicon carbide layer form an ohmic contact or a Schottky contact; and
forming a principal layer on the contact layer, wherein the principal layer comprises at least one of aluminum and copper.

33. The method of claim 32,
wherein the separation trench is formed after forming the principal layer.

34. The method of claim 32,
wherein the separation trench is formed after forming the contact layer and the principal layer is formed after forming the glass fill structure.

35. The method of claim 34,
wherein a section of the principal layer is formed on a section of the glass fill structure.

36. The method of claim 27, further comprising:
thinning, before separating, the silicon carbide layer from a side opposite to the main surface, wherein the glass fill structure is exposed.

37. The method of claim 27, further comprising:
forming gate electrode structures in the silicon carbide layer,
wherein forming the gate electrode structures comprises:
forming gate trenches extending from the main surface into the silicon carbide layer; and
forming gate electrodes in the gate trenches,
wherein the separation trench is formed before forming the gate electrodes.

38. The method of claim 37, further comprising:
filling the separation trench with an auxiliary material before forming the gate electrodes; and
removing the auxiliary material after forming the contact layer.
